(19) United States
(12) Patent Application Publication
(10) Pub. No.: US 2025/0306284 A1
(43) Pub. Date: Oct. 2, 2025

(54) METHODS AND SYSTEMS FOR OPTICAL TRANSMITTERS EXPLOITING MULTIPLE GAIN ELEMENTS

(71) Applicants: DAMIEN MICHEL, BROMONT (CA); ANDRE FEKECS, SHERBROOKE (CA); JUSTIN ALEXANDER, GATINEAU (CA); MARTIN BERARD, STE-CATHERINE-DE-LA-JACQUES CARTIER (CA)

(72) Inventors: DAMIEN MICHEL, BROMONT (CA); ANDRE FEKECS, SHERBROOKE (CA); JUSTIN ALEXANDER, GATINEAU (CA); MARTIN BERARD, STE-CATHERINE-DE-LA-JACQUES CARTIER (CA)

(21) Appl. No.: 18/864,143

(22) PCT Filed: May 9, 2023
(86) PCT No.: PCT/CA2023/050630

§ 371 Date: Nov. 8, 2024

Related U.S. Application Data
(60) Provisional application No. 63/339,774, filed on May 9, 2022.

(51) Int. Cl. G02B 6/293; G02B 6/42; H01S 5/00; H01S 5/14; H01S 5/40

(52) U.S. Cl. CPC G02B 6/2938; G02B 6/4215; H01S 5/0064; H01S 5/141; H01S 5/4025

(57) ABSTRACT

Silicon photonics adds optical functionality to electronic integrated circuits allowing leveraging CMOS fabrication processes, integration of CMOS electronics discretely and integration of microelectromechanical systems (MEMS) or Micro-Opto-Electro-Mechanical-Systems (MOEMS) elements. Further, silicon photonics allows hybrid or monolithic integration of semiconductor photodetectors in conjunction with the passive silicon photonics and active elements such as semiconductor optical amplifiers (SOAs). Accordingly, it would be beneficial to provide network designers with silicon photonic optical emitters and transmitters for wavelength division multiplexed networks which can dynamically transmit on one or more channels whilst addressing the inherent issues that silicon photonics and other optical waveguide technologies exhibit for hybrid integration of SOAs and passive photonics.

### CROSS-REFERENCE TO RELATED APPLICATIONS

This patent application claims the benefit of priority as a 371 national phase entry application of PCT/CA2023/050630 filed May 9, 2023; which itself claims the benefit of priority from U.S. Provisional Patent Application 63/339,774 filed May 9, 2022; the entire contents of each being incorporated herein by reference.

### FIELD OF THE INVENTION

This invention is directed to optical transmitters and optical sources and more particularly to methods and systems for implementing optical transmitters and optical sources exploiting multiple gain elements.

### BACKGROUND OF THE INVENTION

Photonics has become a dominant or evolving technological solution in a wide range of applications from sensing, biomedical sensing, to quantum computing, quantum sensing, and telecommunications. Core to all of these is the optical source, i.e., the laser. Accordingly, it would be beneficial to provide designers with enhanced optical sources which can be implemented using monolithic or hybrid integration methodologies.

Other aspects and features of the present invention will become apparent to those ordinarily skilled in the art upon review of the following description of specific embodiments of the invention in conjunction with the accompanying figures.

### SUMMARY OF THE INVENTION

It is an object of the present invention to mitigate limitations in the prior art relating to optical transmitters and optical sources and more particularly to methods and systems for implementing optical transmitters and optical sources exploiting multiple gain elements.

In accordance with an embodiment of the invention there is provided an optical emitter comprising a wavelength specific optical portion for defining one or more wavelengths of an optical signal emitted by the optical emitter and an optical gain portion for generating the optical signal.

In accordance with an embodiment of the invention there is provided an optical emitter comprising a wavelength specific optical portion for defining one or more wavelengths of an optical signal emitted by the optical emitter and an optical gain portion for generating the optical signal; where
the wavelength specific optical portion comprises:
   a wavelength dependent reflective filter settable to a predetermined centre wavelength within a defined wavelength range and a predetermined passband; and
   an optical splitter having an input port and a plurality of output ports wherein the input port is optically coupled to the wavelength dependent reflective filter; and
the optical gain portion comprises:
   a plurality of optical gain elements each having an input port and an output port; wherein
the input port of each optical gain element of the plurality of optical gain elements is coupled to a predetermined output port of the plurality of output ports of the optical splitter;
each output port of each optical gain element of the plurality of optical gain elements is optically coupled to a high reflectivity facet; and
the optical emitter generates a plurality of optical outputs from each high reflectivity facet of the plurality of optical gain elements with an optical emission spectrum defined by the wavelength dependent reflective filter.

In accordance with an embodiment of the invention there is provided an optical emitter comprising a wavelength specific optical portion for defining one or more wavelengths of an optical signal emitted by the optical emitter and an optical gain portion for generating the optical signal; where
the wavelength specific optical portion comprises:
   a wavelength dependent reflective filter settable to a predetermined centre wavelength within a defined wavelength range and a predetermined passband; and
   an optical switch comprising an input port and a plurality of output ports wherein the input port is optically coupled to the wavelength dependent reflective filter and optical signals at the input port are switchably coupled to one output port of the plurality of output ports; and
the optical gain portion comprises:
   a plurality of optical gain elements each heaving an input port and an output port; wherein
the input port of each optical gain element of the plurality of optical gain elements is coupled to a predetermined output port of the plurality of output ports of the optical switch;
each output port of each optical gain element of the plurality of optical gain elements is optically coupled to a high reflectivity facet; and
the optical emitter generates a plurality of optical outputs from each high reflectivity facet of the plurality of optical gain elements with an optical emission spectrum defined by the wavelength dependent reflective filter.

In accordance with an embodiment of the invention there is provided an optical emitter comprising a wavelength specific optical portion for defining one or more wavelengths of an optical signal emitted by the optical emitter and an optical gain portion for generating the optical signal; where
the wavelength specific optical portion comprises:
   a plurality of wavelength dependent reflective filters where each wavelength dependent reflective filter having a predetermined centre wavelength and a predetermined passband;
   an optical splitter having a plurality of input ports and a plurality of output ports wherein each input port is optically coupled to a predetermined wavelength dependent reflective filter of the plurality of wavelength dependent reflective filters; and
the optical gain portion comprises:
   a plurality of optical gain elements each having an input port and an output port; wherein
the input port of each optical gain element of the plurality of optical gain elements is coupled to a predetermined output port of the plurality of output ports of the optical splitter;
each output port of each optical gain element of the plurality of optical gain elements is optically coupled to a high reflectivity facet; and
the optical emitter generates a plurality of optical outputs from each high reflectivity facet of the plurality of optical gain elements with an optical emission spectrum defined by the plurality of wavelength dependent reflective filters.

In accordance with an embodiment of the invention there is provided an optical emitter comprising a wavelength specific optical portion for defining one or more wavelengths of an optical signal emitted by the optical emitter and an optical gain portion for generating the optical signal; where
the wavelength specific optical portion comprises:
   a plurality R wavelength dependent reflective filters where each wavelength dependent reflective filter having a predetermined centre wavelength and a predetermined passband;
   an optical splitter having a plurality N input ports and a plurality M output ports; and
   a plurality N-R reflectors;
the optical gain portion comprises:
   a plurality M optical gain elements each having an input port and an output port; wherein
the input port of each optical gain element of the plurality M optical gain elements is coupled to a predetermined output port of the plurality M output ports of the optical splitter;
each output port of each optical gain element of the plurality of optical gain elements is optically coupled to a high reflectivity facet;
R inputs ports of the optical splitter are optically coupled to a predetermined wavelength dependent reflective filter of the plurality R wavelength dependent reflective filters;
N-R inputs ports of the optical splitter are optically coupled to a reflector of the plurality N-R reflectors;
the optical emitter generates a plurality of optical outputs from each high reflectivity facet of the plurality of optical gain elements with an optical emission spectrum defined by the plurality R wavelength dependent reflective filters;
R is an integer greater than or equal to 1; N is an integer greater than or equal to 2; and M is an integer greater than or equal to 1.

In accordance with an embodiment of the invention there is provided an optical emitter comprising a wavelength specific optical portion for defining one or more wavelengths of an optical signal emitted by the optical emitter and an optical gain portion for generating the optical signal; where
the wavelength specific optical portion comprises:
   a plurality R wavelength dependent reflective filters where each wavelength dependent reflective filter having a predetermined centre wavelength and a predetermined passband;
   an optical splitter having a plurality T input ports and a plurality M output ports;
   an optical switch having N input ports and T output ports; and
   a plurality N-R reflectors;
the optical gain portion comprises:
   a plurality M optical gain elements each having an input port and an output port; wherein
the input port of each optical gain element of the plurality M optical gain elements is coupled to a predetermined output port of the plurality M output ports of the optical splitter;
each output port of each optical gain element of the plurality of optical gain elements is optically coupled to a high reflectivity facet;
R inputs ports of the optical switch are optically coupled to a predetermined wavelength dependent reflective filter of the plurality R wavelength dependent reflective filters;
N-R inputs ports of the optical switch are optically coupled to a reflector of the plurality N-R reflectors;
each of the output ports of the optical switch is coupled to an input port of the optical splitter;
the optical emitter generates a plurality of optical outputs from each high reflectivity facet of the plurality of optical gain elements with an optical emission spectrum defined by the wavelength dependent reflective filters of the plurality R wavelength dependent reflective filters coupled to the optical splitter by the optical switch;
R is an integer greater than or equal to 1; N is an integer greater than or equal to 2; T is an integer greater than or equal to 1; and M is an integer greater than or equal to 1.

In accordance with an embodiment of the invention there is provided an optical emitter comprising a wavelength specific optical portion for defining one or more wavelengths of an optical signal emitted by the optical emitter and an optical gain portion for generating the optical signal; where
the wavelength specific optical portion comprises:
   a wavelength dependent reflective filter settable to a predetermined centre wavelength within a defined wavelength range and a predetermined passband; and
the optical gain portion comprises:
   a first optical gain element forming part of an external cavity laser in conjunction with the wavelength dependent reflective filter; and
   a plurality N second optical gain elements; wherein
an output port of the external cavity laser is coupled to an input port of an isolator;
an output port of the isolator is coupled to an input port of a 1×N optical splitter;
an end of optical gain element of the plurality N second optical gain elements is coupled to a defined output port of the optical splitter;
the optical emitter generates a plurality of optical outputs from a distal end of each of the plurality N second optical gain elements with an optical emission spectrum defined by the wavelength dependent reflective filter; and
N is an integer greater than or equal to 2.

In accordance with an embodiment of the invention there is provided an optical emitter comprising a wavelength specific optical portion for defining one or more wavelengths of an optical signal emitted by the optical emitter and an optical gain portion for generating the optical signal; where
the wavelength specific optical portion comprises:
   a first wavelength dependent reflective filter having a predetermined passband and a first free spectral range settable to a predetermined centre wavelength within a defined wavelength range; and
   a second wavelength dependent reflective filter having a predetermined passband and a second free spectral range settable to another predetermined centre wavelength within the defined wavelength range; and
   an N×2 optical splitter having N input ports, a first output port coupled to the first wavelength dependent reflective filter and a second output port coupled to the second wavelength dependent reflective filter; and
the optical gain portion comprises:
   a plurality of N optical gain elements each having an input port and an output port; wherein
the input port of each optical gain element of the plurality N optical gain elements is coupled to a predetermined input port of the N×2 optical splitter;
each output port of each optical gain element of the plurality of optical gain elements is optically coupled to a high reflectivity facet;
the optical emitter generates one or more outputs at a wavelength where the reflectivity of the first wavelength dependent reflective filter and the second wavelength dependent reflective filter align; and
N is an integer greater than or equal to 2.

In accordance with an embodiment of the invention there is provided an optical emitter comprising a wavelength specific optical portion for defining one or more wavelengths of an optical signal emitted by the optical emitter and an optical gain portion for generating the optical signal; where
the wavelength specific optical portion comprises:
   a first wavelength dependent reflective filter having a predetermined passband and a first free spectral range settable to a predetermined centre wavelength within a defined wavelength range; and
   a second wavelength dependent reflective filter having a predetermined passband and a second free spectral range settable to another predetermined centre wavelength within the defined wavelength range; and
   an N×2 optical splitter having N input ports, a first output port coupled to the first wavelength dependent reflective filter and a second output port coupled to the second wavelength dependent reflective filter; and
the optical gain portion comprises:
   a plurality of N optical gain elements each having an input port and an output port; wherein
the input port of each optical gain element of the plurality N optical gain elements is coupled to a predetermined input port of the N×2 optical splitter;
each output port of each optical gain element of the plurality of optical gain elements is optically coupled to a high reflectivity facet;
the optical emitter generates one or more outputs at a wavelength defined by a vernier overlay of the periodic wavelength response defined by the first free spectral range of the first wavelength dependent reflective filter and the other periodic wavelength response defined by the second free spectral range of the second wavelength dependent reflective filter; and
N is an integer greater than or equal to 2.

In accordance with an embodiment of the invention there is provided an optical emitter comprising a wavelength specific optical portion for defining one or more wavelengths of an optical signal emitted by the optical emitter and an optical gain portion for generating the optical signal; where
the optical gain portion comprises an optical splitter coupled to the wavelength specific optical portion having a plurality N outputs;
an output of the N outputs of the optical splitter is coupled to a wavelength locker;
the other N−1 outputs of the optical splitter each comprise an optical gain element and a high reflectivity reflector; and
N is an integer greater than or equal to 2.

In accordance with an embodiment of the invention there is provided an optical emitter comprising a wavelength specific optical portion for defining one or more wavelengths of an optical signal emitted by the optical emitter and an optical gain portion for generating the optical signal; where
the wavelength specific optical portion comprises:
a plurality of wavelength selective optical switch (WSOS) elements coupled in series wherein the first WSOS element of the plurality of WSOS elements is coupled to a first input port of the wavelength specific optical portion and each sequential WSOS element of the plurality of WSOS elements has a free spectral range (FSR) equal to the FSR of the preceding WSOS of the plurality of WSOS elements multiplied by a first constant;
a plurality of gates where each gate is disposed between an output port of the wavelength specific optical portion and a high reflectivity reflector and is configurable to either pass optical signals from the output port of the wavelength specific optical portion to the high reflectivity reflector or block the optical signals; and
the optical emitter generates one or more outputs at a wavelength defined by which gate or gates pass optical signals from their output port of the wavelength specific optical portion to the associated high reflectivity reflector.

In accordance with an embodiment of the invention there is provided an optical emitter comprising a wavelength specific optical portion for defining one or more wavelengths of an optical signal emitted by the optical emitter and an optical gain portion for generating the optical signal; where
the wavelength specific optical portion comprises:
   a plurality of wavelength selective optical switch (WSOS) elements coupled in series wherein the first WSOS element of the plurality of WSOS elements is coupled to a first output of an input port of the wavelength specific optical portion and each sequential WSOS element of the plurality of WSOS elements has a free spectral range (FSR) equal to the FSR of the preceding WSOS of the plurality of WSOS elements multiplied by a first constant;
a plurality of gates where each gate is disposed between an output port of the wavelength specific optical portion and a high reflectivity reflector and is configurable to either pass optical signals from the output port of the wavelength specific optical portion to the high reflectivity reflector or block the optical signals;
the optical emitter generates one or more outputs at a wavelength defined by which gate or gates pass optical signals from their output port of the wavelength specific optical portion to the associated high reflectivity reflector; and
each WSOS element of the plurality of WSOS elements comprises an optical de-interleaver (D-INT) having a pair of outputs and an optical switch (OS) coupled to the pair of outputs of the D-INT;
in the first state the OS selects an output of the pair of outputs of the D-INT and in the second state the OS selects the other output of the pair of outputs of the D-INT.

In accordance with an embodiment of the invention there is provided an optical emitter comprising a wavelength specific optical portion for defining one or more wavelengths of an optical signal emitted by the optical emitter and an optical gain portion for generating the optical signal; where
the wavelength specific optical portion comprises:
   a plurality of wavelength selective optical switch (WSOS) elements coupled in series wherein the first WSOS element of the plurality of WSOS elements is coupled to a first output of an input port of the wavelength specific optical portion and each sequential WSOS element of the plurality of WSOS elements has a free spectral range (FSR) equal to the FSR of the preceding WSOS of the plurality of WSOS elements multiplied by a first constant;
each WSOS element of the plurality of WSOS elements is dynamically configurable between a first state and a second state such that the plurality of WSOS elements filter an incoming optical stream of a plurality optical signals having a predetermined channel spacing;
in the first state each WSOS element of the plurality of WSOS elements passes a first subset of those wavelengths coupled to it and in the second state each WSOS element of the plurality of WSOS elements passes a second subset of those wavelengths coupled to it.

In accordance with an embodiment of the invention there is provided an optical emitter comprising a wavelength specific optical portion for defining one or more wavelengths of an optical signal emitted by the optical emitter and an optical gain portion for generating the optical signal; where
the wavelength specific optical portion comprises:
   a plurality of wavelength selective optical switch (WSOS) elements coupled in series wherein the first WSOS element of the plurality of WSOS elements is coupled to a first output of an input port of the wavelength specific optical portion and each sequential WSOS element of the plurality of WSOS elements has a free spectral range (FSR) equal to the FSR of the preceding WSOS of the plurality of WSOS elements multiplied by a first constant;
each WSOS element of the plurality of WSOS elements is dynamically configurable between a first state and a second state such that the plurality of WSOS elements filter an incoming optical stream of a plurality optical signals having a predetermined channel spacing;
in the first state each WSOS element of the plurality of WSOS elements passes a first subset of those wavelengths coupled to it;
in the second state each WSOS element of the plurality of WSOS elements passes a second subset of those wavelengths coupled to it; and
each WSOS element of the plurality of WSOS elements comprises an optical de-interleaver (D-INT) having a pair of outputs and an optical switch (OS) coupled to the pair of outputs of the D-INT where in the first state the OS selects an output of the pair of outputs of the D-INT and in the second state the OS selects the other output of the pair of outputs of the D-INT.

Other aspects and features of the present invention will become apparent to those ordinarily skilled in the art upon review of the following description of specific embodiments of the invention in conjunction with the accompanying figures.

### BRIEF DESCRIPTION OF THE DRAWINGS

Embodiments of the present invention will now be described, by way of example only, with reference to the attached Figures, wherein:

FIG. 1 depicts a block structure for a hybrid integrated external cavity laser according to an embodiment of the invention;

FIG. 2 depicts a block structure for a coupled cavity hybrid integrated external cavity laser according to an embodiment of the invention;

FIG. 3 depicts a block structure for a hybrid integrated external cavity laser with a pair of gain blocks according to an embodiment of the invention;

FIG. 4 depicts a block structure for a hybrid integrated external cavity laser with an array of gain blocks according to an embodiment of the invention;

FIG. 5 depicts a generalized functional schematic of an optical transmitter according to an embodiment of the invention;

FIG. 6 depicts a generalized functional schematic of an optical transmitter according to an embodiment of the invention;

FIG. 7 depicts a generalized functional schematic of an optical transmitter according to an embodiment of the invention;

FIG. 8 depicts a generalized functional schematic of an optical transmitter according to an embodiment of the invention;

FIG. 9 depicts a generalized functional schematic of an optical transmitter according to an embodiment of the invention;

FIG. 10 depicts a generalized functional schematic of an optical transmitter according to an embodiment of the invention;

FIG. 11 depicts a generalized functional schematic of an optical transmitter according to an embodiment of the invention;

FIG. 12 depicts a Switchable 8 Wavelength Filter for multiple wavelength setting/tunability of an optical transmitter according to an embodiment of the invention;

FIG. 13 depicts an exemplary Switchable Wavelength Optical Transmitter Filter (SWOTF) circuit exploiting cascaded deinterleaving and optical switching to band select prior to a wavelength selective reflector;

FIG. 14A depicts an exemplary cascade of Mach-Zehnder deinterleavers in which an interferometric optical switching circuits is incorporated within a de-interleaving stage or a plurality of deinterleaving stages of a Switchable Wavelength Optical Transmitter Filter (SWOTF) according to an embodiment of the invention;

FIG. 14B depicts an exemplary cascade of Mach-Zehnder deinterleavers in which an integrated optics MEMS optical switching circuit is incorporated within a deinterleaving stage or a plurality of deinterleaving within a SWOTF according to an embodiment of the invention;

FIG. 15A depicts an exemplary Switchable Wavelength Optical Transmitter Filter (SWOTF) employing a cascade of wavelength selective optical switches (WSOS) according to an embodiment of the invention, wherein the optical switching function of each stage is embedded inside the deinterleaving function of that stage;

FIG. 15B depicts an exemplary Switchable Wavelength Optical Transmitter Filter (SWOTF) employing a cascade of wavelength selective optical switches (WSOS) which have their second input port connected to an additional optical switch and monitoring photodetector to provide feedback for circuit calibration, monitoring and configuration;

FIG. 16 depicts a polarisation diverse SWOTF exploiting WSOS based Mach-Zehnder deinterleavers with integrated optical switching according to an embodiment of the invention with improved polarisation extinction;

FIG. 17 depicts a polarisation diverse SWOTF exploiting WSOS based Mach-Zehnder deinterleavers with integrated optical switching according to an embodiment of the invention making use of a polarisation combiner to clean up residual polarisation crosstalk and to reduce the number of a waveguides facing the high-speed photodetector to a single waveguide;

FIG. 18A depicts a schematic of a mechanical structure for the formation of a photonic wire bond (PWB) between a graded index optical fiber within a U- or V-groove formed within a silicon substrate and an optical waveguide formed upon the silicon substrate according to an embodiment of the invention wherein the graded index optical fiber is coupled to another optical element;

FIG. 18B depicts a schematic of a mechanical structure for the formation of a photonic wire bond (PWB) between an optical waveguide formed upon a silicon substrate according to an embodiment of the invention and another optical element;

FIG. 19 depicts a schematic of PWB interconnections between a pair of optical fibers and an optical element according to an embodiment of the invention;

FIG. 20 depicts the integration of an intermediate support die (ISD) die with a thin film active element (e.g. SOA) within an integrated photonics silicon chip (IPSC) according to an embodiment of the invention;

FIG. 21 depicts a schematic of an IPSC showing the optical fiber and ISD sections according to an embodiment of the invention with a thin film active ISD die and dual PWB sections; and

FIG. 22 depicts a schematic of an IPSC for a hybrid integrated external cavity laser with a pair of gain blocks according to an embodiment of the invention.

### DETAILED DESCRIPTION

The present invention is directed to optical transmitters and optical sources and more particularly to methods and systems for implementing optical transmitters and optical sources exploiting multiple gain elements.

The ensuing description provides representative embodiment(s) only, and is not intended to limit the scope, applicability or configuration of the disclosure. Rather, the ensuing description of the embodiment(s) will provide those skilled in the art with an enabling description for implementing an embodiment or embodiments of the invention. It would be understood by one of skill in the art that various changes can be made in the function and arrangement of elements without departing from the scope of the invention as set forth in the claims. Accordingly, an embodiment is an example or implementation of the inventions and not the sole implementation. Various appearances of “one embodiment,” “an embodiment” or “some embodiments” do not necessarily all refer to the same embodiments. Although various features of the invention may be described in the context of a single embodiment, the features may also be provided separately or in any suitable combination. Conversely, although the invention may be described herein in the context of separate embodiments for clarity, the invention can also be implemented in a single embodiment or any combination of embodiments.

Reference in the specification to “one embodiment,” “an embodiment,” “some embodiments” or “other embodiments” means that a particular feature, structure, or characteristic described in connection with the embodiments is included in at least one embodiment, but not necessarily all embodiments, of the inventions. The phraseology and terminology employed herein is not to be construed as limiting but is for descriptive purposes only. It is to be understood that where the claims or specification refer to “a” or “an” element, such reference is not to be construed as there being only one of that element. It is to be understood that where the specification states that a component feature, structure, or characteristic “may,” “might,” “can” or “could” be included, that particular component, feature, structure, or characteristic is not required to be included.

Reference to terms such as “left,” “right,” “top,” “bottom”, “front” and “back” are intended for use in respect to the orientation of the particular feature, structure, or element within the figures depicting embodiments of the invention. It would be evident that such directional terminology with respect to the actual use of a device has no specific meaning as the device can be employed in a multiplicity of orientations by the user or users.

Reference to terms “including,” “comprising,” “consisting” and grammatical variants thereof do not preclude the addition of one or more components, features, steps, integers or groups thereof and that the terms are not to be construed as specifying components, features, steps or integers. Likewise, the phrase “consisting essentially of,” and grammatical variants thereof, when used herein is not to be construed as excluding additional components, steps, features integers or groups thereof but rather that the additional features, integers, steps, components or groups thereof do not materially alter the basic and novel characteristics of the claimed composition, device or method. If the specification or claims refer to “an additional” element, that does not preclude there being more than one of the additional elements.

A “two-dimensional” waveguide, also referred to as a 2D waveguide or a planar waveguide, as used herein may refer to, but is not limited to, an optical waveguide supporting propagation of optical signals within a predetermined wavelength range which does not guide the optical signals laterally relative to the propagation direction of the optical signals.

A “three-dimensional” waveguide, also referred to as a 3D waveguide, a channel waveguide, or simply waveguide as used herein may refer to, but is not limited to, an optical waveguide supporting propagation of optical signals within a predetermined wavelength range which guides the optical signals laterally relative to the propagation direction of the optical signals.

A “wavelength division de-interleaver” (WDM D-INT or D-INT) as used herein may refer to, but is not limited to, an optical device for separating (deinterleaving) multiple optical signals of different wavelengths, cyclically repeating on a given free spectral range, which are received on a common optical waveguide, e.g. a waveguide forming part of a photonic integrated circuit or an optical fiber. For example, such a D-INT may exploit a Mach-Zehnder interferometer wherein a single input port carrying optical signals is split into 2 outputs each carrying optical signals at different predetermined wavelengths.

“Waveguide crosstalk” as used herein refers to, but is not limited to, optical cross-coupling between adjacent and non-adjacent optical waveguides.

“Crosstalk penalty” as used herein refers to, but is not limited to, inter-channel crosstalk stemming from multiple WDM signals within a passband of a channel reducing the wavelength extinction ratio of the wavelength division deinterleavers (D-INT).

A “photonic integrated circuit” (PIC) as used herein may refer to, but is not limited to, the monolithic integration of multiple integrated optics devices into a circuit formed upon a common substrate providing an optical routing and processing functionality. The PIC is fabricated using processing techniques at a wafer level, e.g. CMOS manufacturing flows, MEMS processing flows, etc.

A “high reflectivity facet” as used herein and throughout this disclosure refers to, but is not limited to, a facet or coated facet reflecting optical signals to an optical gain element (e.g., semiconductor optical amplifier (SOA)) having a minimum reflectivity over a predetermined wavelength range commensurate with the establishment of lasing within an optical cavity comprising the optical gain element disposed between the high reflectivity facet and either another high reflectivity facet or wavelength specific reflector with high reflectivity.

A “Bragg grating reflector” or “wavelength specific reflector” as used herein and throughout this disclosure refers to, but is not limited to, a reflective Bragg grating or other wavelength dependent reflector reflecting optical signals to an optical gain element (e.g., semiconductor optical amplifier (SOA)) having a minimum reflectivity over a defined wavelength range commensurate with the establishment of lasing within an optical cavity comprising the optical gain element disposed between the Bragg grating device or wavelength specific reflector and another high reflectivity facet.

An additive manufacturing methodology may, within embodiments of the invention employ one or more additive manufacturing (AM) steps selected from the group, using the American Society for Testing and Materials (ASTM) categorizations, material jetting, powder bed fusion, binder jetting, direct energy deposition, material extrusion, sheet lamination, and polymerization. Energy sources for such AM steps may include, but not be limited to, an emitted signal selected from the group comprising infrared (IR) radiation, visible radiation, ultraviolet (UV) radiation, microwave radiation, radio frequency (RF) radiation, X-ray radiation, electron beam radiation, ion beam radiation, an ultrasonic signal, an acoustic signal, a hypersonic signal, a magnetic field and an electric field. Other additive manufacturing techniques may be employed including, for example, those described by Habibi et al. in WO/2022/011456 and Packirisamy et al in WO/2018/145194.

Within the embodiments of the invention the inventors refer to the term “hybridly integrated.” This may, within some embodiments of the invention, refer to, but not be limited to, the “integration” of an optical element onto a substrate by attaching the optical element or another element physically integrated with the optical element to the substrate (platform) such that the optical element is retained in position. Such attachment means may include, but not be limited to, soldering, epoxy, van der Waals forces, electrostatic attachment, magnetic attachment, physical interlocking and friction. Accordingly, in these embodiments of the invention the optical element being hybridly integrated may be viewed as being implemented within a parallel manufacturing process to the other optical element(s) prior to being co-assembled. This parallel manufacturing process may employ one or more processes selected from the group comprising, but not limited to, liquid phase epitaxy (LPE), metal organic chemical vapor deposition (MOCVD), organometallic vapour-phase epitaxy (OMVPE), selective area epitaxy, an additive manufacturing process, a non-additive manufacturing process, crystal growth, doping, induced damage, etching, doping and deposition.

This may, within other embodiments of the invention, refer to, but not be limited to, the “integration” of an optical element onto a substrate using a different manufacturing methodology and/or techniques to those employed in forming other optical components upon the substrate. For example, this may employ employing a LPE process to form the other optical element upon the substrate wherein the optical component upon the substrate was formed by MOCVD or vice-versa. Alternatively, both the optical component and other optical component may be formed using the same manufacturing methodology or a combination of manufacturing methodologies. These manufacturing methodologies may employ one or more processes selected from the group comprising, but not limited to, LPE, MOCVD, OMVPE, selective area epitaxy, an additive manufacturing process, a non-additive manufacturing process, crystal growth, doping, induced damage, etching, doping, deposition, an additive manufacturing process and a non-additive manufacturing process. Accordingly, in these embodiments of the invention the optical element being hybridly integrated may be viewed as being implemented within one or more further processing stages of the same manufacturing process as the other optical element(s).

However, in each instance the optical waveguide and/or optical component properties require that an optical interface is implemented between the optical waveguide and optical component in order to provide efficient optical coupling between one and the other.

Examples of semiconductors grown using OMVPE may include, but are not limited to, group III-V semiconductors, II-VI semiconductors, group IV semiconductors, and group IV-V-VI semiconductors. Examples of group III-V semiconductors may include AlP, AlN, AlGaSb, AlGaAs, AlGaInP, AlGaN, AlGaP, GaSb, GaAsP, GaAs, GaN, GaP, InAlAs, InAlP, InSb, InGaSb, InGaN, GaInAlAs, GaInAIN, GaInAsN, GaInAsP, GaInAs, GaInP, InN, InP, InAs, InAsSb, and AlInN. Examples of group II-VI semiconductors may include ZnSe, HgCdTe, ZnO, ZnS, and CdO. Examples of group IV Semiconductors may include Si, Ge, and strained silicon. A group IV-V-VI semiconductor may be GeSbTe.

Within embodiments of the invention an optical element may be disposed between a pair of optical waveguides or between an optical waveguide and another optical element. The optical element may be optically passive, optically active, or a combination of optically passive and optically active elements.

Within embodiments of the invention the optical element may be hybridly integrated onto a platform (i.e. a substrate) where the optical waveguide, the pair of optical waveguides and the another optical element are monolithically integrated upon the platform.

Within embodiments of the invention the optical element may be hybridly integrated onto a platform (i.e. a substrate) where the optical waveguide, the pair of optical waveguides and the another optical element are hybridly integrated upon the platform.

Within embodiments of the invention the optical element may be hybridly integrated onto a platform (i.e. a substrate) where the optical waveguide, the pair of optical waveguides and the another optical element are both monolithically and hybridly integrated upon the platform.

Within a non-limiting example an optical waveguide is coupled to a hybridly integrated optical element which provides optical functionality which is either physically not implementable within the optical waveguide or whilst physically implementable within the optical waveguide cannot be implemented with one or more required optical performance characteristics.

Within embodiments of the invention the platform or substrate upon which the integration is performed may be a silicon substrate wherein the one or more optical waveguides upon the platform exploit a silicon nitride core with silicon oxide upper and lower cladding, a SiO₂—Si₃N₄—SiO₂ waveguide structure. Alternatively, the one or more optical waveguides may employ a silicon core with silicon nitride upper and lower claddings. Optionally, the upper cladding may be omitted within other embodiments of the invention.

However, it would be evident that other optical waveguide structures may be employed including, but not limited to, silica-on-silicon, doped (e.g., germanium, Ge) silica core with undoped cladding, silicon oxynitride, polymer-on-silicon, or doped silicon waveguides for example. Additionally, other waveguide structures may be employed including vertical and/or lateral waveguide tapers and forming microball lenses on the ends of the waveguides via laser and/or arc melting of the waveguide tip.

Further, whilst embodiments of the invention are described primarily with respect to silicon-on-insulator (SOI) waveguides by way of example, e.g. SiO₂—Si₃N₄—SiO₂; SiO₂—Ge:SiO₂—SiO₂; or Si—SiO₂; it would be evident that other embodiments of the invention may be employed to coupled passive waveguides to active semiconductor waveguides, such as indium phosphide (InP) or gallium arsenide (GaAs), e.g. a semiconductor optical amplifier (SOA), laser diode, etc. Optionally, an active semiconductor structure may be epitaxially grown onto a silicon IO-MEMS structure, epitaxially lifted off from a wafer and bonded to a silicon integrated optical microelectromechanical systems (IO-MEMS) structure, etc.

However, within other embodiments of the invention a variety of waveguide coupling structures coupling onto and/or from waveguides employing material systems that include, but not limited to, SiO₂—Si₃N₄—SiO₂; SiO₂—Ge:SiO₂—SiO₂; Si—SiO₂; ion exchanged glass, ion implanted glass, polymeric waveguides, InGaAsP, GaAs, III-V materials, II-VI materials, and optical fiber. Whilst primarily waveguide-waveguide systems have been described it would be evident to one skilled in the art that embodiments of the invention may be employed in aligning intermediate coupling optics, e.g., ball lenses, spherical lenses, graded refractive index (GRIN) lenses, etc. for free-space coupling into and/or from a waveguide device.

Further, whilst embodiments of the invention are described primarily with respect to a silicon substrate it would be evident that other substrates may be employed within other embodiments of the invention. These may include, but not be limited to, a semiconductor, a ceramic, a metal, an alloy, a glass, or a polymer.

A “ceramic” as used herein may refer to, but is not limited to, an inorganic, nonmetallic solid material comprising metal, non-metal or metalloid atoms primarily held in ionic and covalent bonds. Such ceramics may be crystalline materials such as oxide, nitride or carbide materials, elements such as carbon or silicon, and non-crystalline. Exemplary ceramics may include high temperature ceramics or high temperature co-fired ceramics such as alumina (Al2O3), zirconia (ZrO2), and aluminum nitride (AlN) or a low temperature cofired ceramic (LTCC). A LTCC may be formed from a glass-ceramic combination.

A “metal” or “alloy” as used herein may refer to, but is not limited to, a material having good electrical and thermal conductivity. Metals are generally malleable, fusible, and ductile. Metals as used herein may refer to elements such as gold, silver, copper, aluminum, iron, etc. whilst an alloy as used herein refers to a combination of metals such as bronze, stainless steel, steel etc.

A “polymer” as used herein may refer to, but is not limited to, is a large molecule, or macromolecule, composed of many repeated subunits. Such polymers may be natural and synthetic and typically created via polymerization of multiple monomers. Polymers through their large molecular mass may provide unique physical properties, including toughness, viscoelasticity, and a tendency to form glasses and semi-crystalline structures rather than crystals.

A “glass” as used herein may refer to, but is not limited to, a non-crystalline amorphous solid. A glass may be fused quartz, silica, a soda-lime glass, a borosilicate glass, a lead glass, an aluminosilicate glass for example. A glass may include other inorganic and organic materials including metals, aluminates, phosphates, borates, chalcogenides, fluorides, germanates (glasses based on GeO2), tellurites (glasses based on TeO2), antimonates (glasses based on Sb2O3), arsenates (glasses based on As2O3), titanates (glasses based on TiO2), tantalates (glasses based on Ta2O5), nitrates, carbonates, plastics, and an acrylic.

Further, whilst the embodiments of the invention are described and depicted with respect to a waveguide employing a core embedded within a cladding, a so-called buried waveguide, it would be evident that other waveguide geometries such as rib waveguide, diffused waveguide, ridge or wire waveguide, strip-loaded waveguide, slot waveguide, and anti-resonant reflecting optical waveguide (ARROW waveguide), photonic crystal waveguide, suspended waveguide, alternating layer stack geometries, sub-wavelength grating (SWG) waveguides and augmented waveguides (e.g. Si—SiO₂—Polymer). Further, whilst the embodiments of the invention are described and depicted with respect to a step-index waveguide it would be evident that other waveguide geometries such as graded index and hybrid index (combining inverse-step index and graded index) may be employed.

Now referring to FIG. 1 there is depicted a block structure for a hybrid integrated external cavity laser (ECL) 100. As depicted a hybrid integrated external cavity laser comprises:
Monitoring photodiode (MPD) 110;
Silicon nitride facet 120 of a silicon nitride waveguide photonic integrated circuit (PIC) structure 130;
Silicon nitride (SiN or SiNx) waveguide photonic integrated circuit (PIC) structure (SiN PIC) 130 which integrates a Bragg grating reflector (Bragg reflector), for example, onto a silicon substrate;
Photonic wire bond (PWB) 140 coupling optical signals between the SiN PIC 130 and a Semiconductor Gain Block 160;
Low Reflectivity Facet Coating 150 of the Semiconductor Gain Block 160, e.g. an anti-reflection coating between the refractive index of the Semiconductor Gain Block 160 and the PWB 140;
Semiconductor Gain Block 160; and
High Reflectivity Facet Coating 170 of the Semiconductor Gain Block 160.

Accordingly, spontaneous emission optical signals of the Semiconductor Gain Block 160 reflected from the High Reflectivity Facet Coating 170 and the Bragg reflector in the SiN PIC 130 propagate back through the Semiconductor Gain Block 160 and are amplified. However, as the Bragg reflector is wavelength specific unlike the High Reflectivity Facet Coating 170 then as the amplified spontaneous emission builds, the ECL 100 reaches a threshold where it lases thereby emitting optical signals from the High Reflectivity Facet Coating 170, at the wavelength of the Bragg reflector within the ECL 100. If the Semiconductor Gain Block 160 is a GaN semiconductor optical amplifier (SOA) then the ECL 100 can emit at 532 nm, for example, whereas with GaAs or InP based SOAs the ECL 100 may emit in the 850 nm, 1300 nm or 1550 nm regions. By virtue of the Bragg reflector the operating wavelength of the ECL 100 is typically fixed unless thermal tuning of the SiN PIC 130 is employed but this is typically limited to below a couple of nanometers.

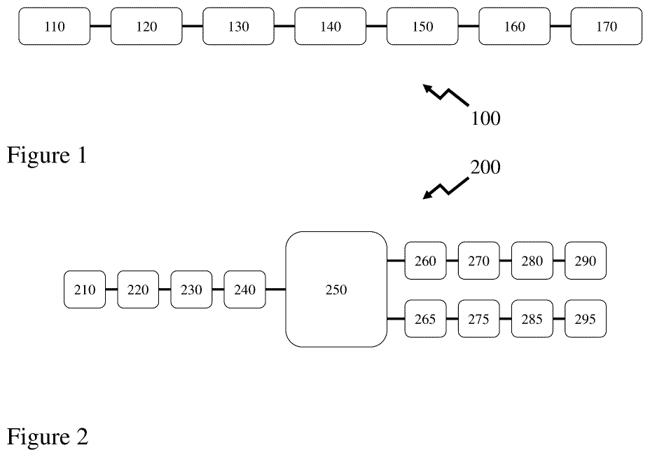

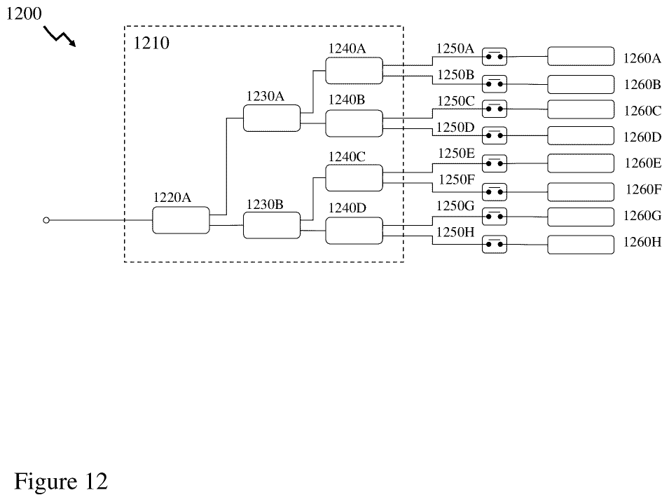

Within embodiments of the invention the SiN facet 120 of the SiN PIC 130 is uncoated or it may be coated with an anti-reflection coating. In other embodiments of the invention the MPD 110 may be omitted and the SiN facet 120 of the SiN PIC 130 coated with an absorber of optical signals in the wavelength range of operation of the ECL 100. These alternate embodiments for the SiN facet 120 of the SiN PIC 130 within an ECL such as ECL 100 may be similarly applied to the other ECL structures described and depicted below in respect of FIGS. 2 to 11 respectively and as employing elements within them such as described and depicted in FIGS. 12 to 21 within embodiments of FIGS. 1 to 11 respectively.

Within other embodiments of the invention the SiN PIC 130 may be a silicon oxide (SiO2 or SiOx) waveguide based PIC, a silicon oxynitride (SiOxNy) waveguide based PIC, or a silicon on insulator (SOI) waveguide where the insulator is typically SiOx or another PIC technology compatible with the required operating wavelength range of the ECL 100. The spectral transparency of SiOx and SiNx waveguides being from approximately 400 nm through to 2500 nm (2.5 μm) whilst SOI waveguides are optical transparent from approximately 1000 nm (1 μm) to 2.5 μm. These alternate embodiments of optical waveguide technology within an ECL such as ECL 100 may be similarly applied to the other ECL structures described and depicted below in respect of FIGS. 2 to 11 respectively and as employing elements within them such as described and depicted in FIGS. 12 to 21 within embodiments of FIGS. 1 to 11 respectively.

Within an alternate embodiment of the invention the Bragg grating reflector within the SiN PIC 130 may be replaced with a tunable filter, such as an etalon filter, Fabry-Perot filter, second order microring resonator (MRRs) etc. Within these embodiments of the invention the tunable filter within the SiN PIC 130 allows the optical resonant cavity formed by the High Reflectivity Facet Coating 170 and the tunable filter to be shifted in wavelength, as defined by the tunable filter, such that the ECL 100 acts as a tunable laser. Within some embodiments of the invention, such as with etalon filters and FP filters for example, this wavelength tuning may be continuous whereas within other embodiments, such as with second order MRRs, this wavelength tuning may be discontinuous or to wavelengths upon a grid. These alternate embodiments for the wavelength filter element within an ECL such as ECL 100 may be similarly applied to the other ECL structures described and depicted below in respect of FIGS. 2 to 11 respectively and as employing elements within them such as described and depicted in FIGS. 12 to 21 within embodiments of FIGS. 1 to 11 respectively.

Optionally, the MPD 110 may be part of a wavelength locker to lock the wavelength of ECL 100 to a defined wavelength or a wavelength of a set of wavelengths where the system to which ECL 100 is connected employs a grid such as those for Synchronous Digital Hierarchy (SDH) and Synchronous Optical Networking (SONET) with Optical Carrier (OC) grids for wavelength division multiplexing (WDM) and coarse WDM such as 50 GHz, 100 GHz, 200 GHz, 400 GHz etc. Alternatively, a wavelength locker may be disposed within the output of ECL 100 via a tap coupler for example. These alternate embodiments employing a wavelength locker within an ECL such as ECL 100 may be similarly applied to the other ECL structures described and depicted below in respect of FIGS. 2 to 11 respectively and as employing elements within them such as described and depicted in FIGS. 12 to 21 within embodiments of FIGS. 1 to 11 respectively.

Within other embodiments of the invention the PWB 140 for coupling optical signals between the SiN PIC 130 and Semiconductor Gain Block 160 may be replaced with another optical interconnection technique such as a micro-lens(es) (e.g. a ball lens or graded refractive index (GRIN) lens), directly written micro-lens(es) into the SiN PIC 140 and/or Semiconductor Gain Block 160 or direct optical interconnection between the SiN PIC 140 and Semiconductor Gain Block 160 such as butt-coupling for example. These alternate embodiments of optical interconnecting optical components within an ECL such as ECL 100 may be similarly applied to the other ECL structures described and depicted below in respect of FIGS. 2 to 11 respectively and as employing elements within them such as described and depicted in FIGS. 12 to 21 within embodiments of FIGS. 1 to 11 respectively.

Within the embodiments of the invention described with respect to FIG. 1 and FIGS. 2 to 21 facet coatings are referred to. These may be directly deposited upon a facet of an optical element, e.g. a Semiconductor Gain Block, or they may be coupled to the facet of the optical element via an air interface and/or intermediate optical elements. A low reflectivity facet coating being designed to provide a reflectivity below a defined threshold at a specific wavelength or over a defined wavelength band and may be an anti-reflection coating or coating designed to couple to a medium beyond the facet of the Semiconductor Gain Block with defined refractive index. A high reflectivity facet coating being designed to provide a reflectivity above another defined threshold at a specific wavelength or over a defined wavelength band.

Referring to FIG. 2 there is depicted a block structure for a coupled cavity hybrid integrated external cavity laser (ECL) 200 according to an embodiment of the invention. As depicted the ECL 200 comprises:
Monitoring photodiode (MPD) 210;
Silicon nitride facet 220 of a first silicon nitride waveguide photonic integrated circuit (PIC) structure 230;
First silicon nitride waveguide photonic integrated circuit (PIC) structure (SiN PIC) 230 which integrates a Bragg grating reflector (Bragg reflector) onto silicon substrate; and
First photonic wire bond (PWB) 240 coupling optical signals between the first SiN PIC 230 and a second SiN PIC 250 which provides a 1×2 splitter/combiner functionality.

Coupled to one output port of the second SiN PIC 250 are:
Second PWB 260;
First Low Reflectivity Facet Coating 270 of the first Semiconductor Gain Block 280, e.g. an anti-reflection coating between the refractive index of the first Semiconductor Gain Block 280 and the second PWB 260;
First Semiconductor Gain Block 280; and
First High Reflectivity Facet Coating 290 of the first Semiconductor Gain Block 280.

Coupled to the other output port of the second SiN PIC 250 are:
Third PWB 265;
Second Low Reflectivity Facet Coating 275 of the second Semiconductor Gain Block 285, e.g. an anti-reflection coating between the refractive index of the second Semiconductor Gain Block 285 and the third PWB 265;
Second Semiconductor Gain Block 285; and
Second High Reflectivity Facet Coating 295 of the second Semiconductor Gain Block 285.

Now, each optical path between the Bragg reflector within the SiN PIC 230 and one of the first High Reflectivity Facet Coating 290 of the first Semiconductor Gain Block 280 and the second High Reflectivity Facet Coating 295 of the second Semiconductor Gain Block 285 acts as an optical cavity amplifying the filtered spontaneous emission until threshold is reached and the optical cavity lases such that the ECL 200 provides two optical sources, each “locked” to the same wavelength through the single common Bragg grating reflector within the SiN PIC 230.

In order to ensure that the optical round-trip paths from the Bragg reflector within the SiN PIC 230 to/from the first High Reflectivity Facet Coating 290 of the first Semiconductor Gain Block 280 and from the Bragg reflector within the SiN PIC 230 to/from the second High Reflectivity Facet Coating 295 of the second Semiconductor Gain Block 285 are aligned in phase, such that the optical signals from these two paths add coherently an optical phase shifter may be implemented in the first output path of second SiN PIC 250 and/or second output path of second SiN PIC 250, e.g. between the splitter within second SiN PIC 250 and the first output port and/or between the splitter and second output port. Alternatively, phase shifter(s) may be integrated within the first Semiconductor Gain Block 280 and/or second Semiconductor Gain Block 285. These phase shifter(s) may be controlled through a feedback loop wherein, for example, a power tap is provided within the SiN PIC 230, for example, coupled to a photodetector.

Within another embodiment of the invention the second SiN PIC 250 incorporates a 2×2 splitter/combiner and an optical switch such that optical signals from are coupled to/from only one of the first Semiconductor Gain Block 280 and second Semiconductor Gain Block 285 with the output of the ECL being the second fourth port of the 2×2 coupler which similarly comprises a reflector of defined reflectivity of a defined wavelength range. In this manner redundancy of the active gain portion of the ECL is provided.

Alternatively within an embodiment of the invention the SiN facet 220 of the SiN PIC 230 is coated to provide a broadband reflector

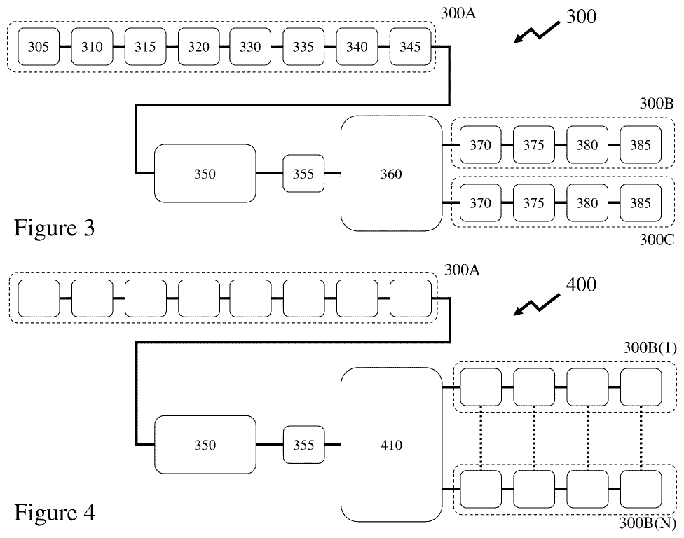

Now referring to FIG. 3 there is depicted a block structure for a hybrid integrated external cavity laser (ECL) 300 with a pair of gain blocks according to an embodiment of the invention. As depicted, the ECL comprises a first Optical Block 300A, an Optical Isolator 350, a third PWB 355, a 1×2 splitter/combiner functionality within a second SiN PIC 360, a second Optical Block 300B and a third Optical Block 300C.

First Optical Block 300A comprises:
Monitoring photodiode (MPD) 305;
Silicon nitride facet 310 of a silicon nitride waveguide photonic integrated circuit (PIC) structure 315;
Silicon nitride waveguide photonic integrated circuit (PIC) structure (SiN PIC) 315 which integrates a Bragg grating reflector (Bragg reflector) onto silicon substrate;
First photonic wire bond (PWB) 320 coupling optical signals between the SiN PIC 315 and a Semiconductor Gain Block 335;
Low Reflectivity Facet Coating 330 of the Semiconductor Gain Block 335, e.g. an anti-reflection coating between the refractive index of the Semiconductor Gain Block 335 and the first PWB 320;
Semiconductor Gain Block 335;
High Reflectivity Facet Coating 340 of the Semiconductor Gain Block 335; and.
Second PWB 345 optically couples the output of the High Reflectivity Facet Coating 340 of the Semiconductor Gain Block 335 to an input of Optical Isolator 350.

The output of the Optical Isolator 350 is coupled to third PWB 355 and therein to second SiN PIC 360 which provides a 1×2 splitter/combiner functionality such that the dual outputs of the second SiN PIC 360 is coupled to the second Optical Block 300B and third Optical Block 300C. Each of the second Optical Block 300B and third Optical Block 300C comprises:
Fourth PWB 370;
Second Low Reflectivity Facet Coating 375 of a second Semiconductor Gain Block 380, e.g. an anti-reflection coating between the refractive index of the second Semiconductor Gain Block 380 and the fourth PWB 370;
Second Semiconductor Gain Block 380; and
Third Low Reflectivity Facet Coating 385 of the second Semiconductor Gain Block 380.

Now, the optical path between the Bragg reflector within the SiN PIC 315 and the High Reflectivity Facet Coating 340 of the Semiconductor Gain Block 335 in first Optical Block 300A acts as an optical cavity amplifying the filtered spontaneous emission until threshold is reached and the optical cavity lases wherein the output is then amplified within the ECL 300 by the second Optical Block 300B and third Optical Block 300C such that ECL 300 provides two optical sources each locked to the same wavelength through the Bragg grating reflector within the SiN PIC 230.

Optionally, a phase shifter may be implemented between an output of the second SiN PIC 360 and second Optical Block 300B and/or another phase shifter may be implemented between another output of the second SiN PIC 360 third Optical Block 300C. Optionally, the second SiN PIC 360 may provide switching functionality rather than passive splitter functionality.

Optionally, the High Reflectivity Facet Coating 340 may be a low reflectivity facet and the Optical Isolator 350 removed such that the overall lasing cavity is between the Bragg reflector within the SiN PIC 315 and the second Low Reflectivity Facet Coating 385 of the second Semiconductor Gain Block 380 in each of the second Optical Block 300B and third Optical Block 300C replaced with a High Reflectivity Facet Coating such that each of the first Optical Block 300A with second Optical Block 300B and first Optical Block 300A and third Optical Block 300A acts as an optical cavity amplifying the filtered spontaneous emission until threshold is reached and the optical cavity lases such that the ECL 300 provides two optical sources each locked to the same wavelength through the Bragg grating reflector within the SiN PIC 315.

Referring to FIG. 4 there is depicted a block structure for a hybrid integrated external cavity laser ECL 400 with an array of gain blocks to an embodiment of the invention. As depicted ECL 400 comprises a first Optical Block 300A, an Optical Isolator 350, a third PWB 355, a 1×N splitter/combiner functionality within a SiN PIC 410, and N second Optical Blocks 300B(1) to 300B(N). Accordingly, the ECL 400 provides a generalized implementation of ECL 300 in FIG. 3 wherein N is a positive integer equal to or greater than 2 such the ECL 400 provides N outputs all locked to the same wavelength through the Bragg grating reflector within first Optical Block 300A. Similarly, where the Bragg grating reflector is replaced with a tunable wavelength filter the ECL 400 provides N outputs all locked to the same wavelength through the tunable filter wavelength filter within first Optical Block 300A.

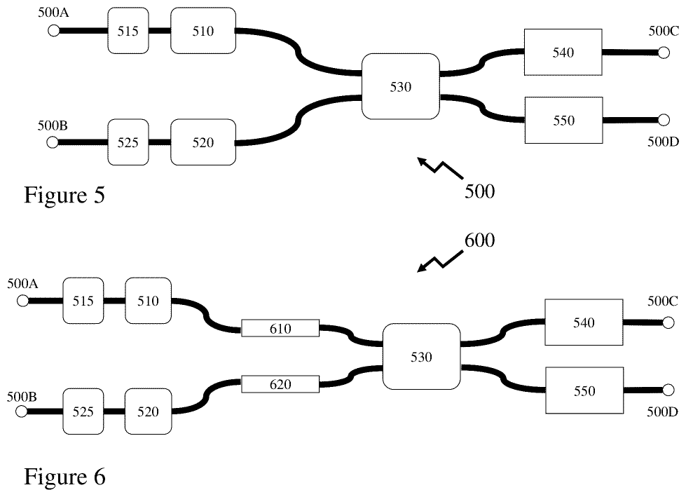

Referring to FIG. 5 there is depicted a generalized functional schematic of an optical transmitter (Tx) 500 according to an embodiment of the invention. Tx 500 as depicted comprises a 2×2 Coupler 530 and first to fourth Ports 500A to 500D respectively. Disposed between the first Port 500A and the 2×2 Coupler 530 are first Optical Gain Block 510 and first Reflector 515. Disposed between the second Port 500B and the 2×2 Coupler 530 are second Optical Gain Block 520 and second Reflector 525. Disposed between the third Port 500C and the 2×2 Coupler 530 is third Reflector 540. Disposed between the fourth Port 500D and the 2×2 Coupler 530 is fourth Reflector 550. If the third Reflector 540 and fourth Reflector 550 are wavelength selective reflectors and the first Reflector 515 and second Reflector 525 are high reflectivity mirrors (e.g. coatings upon each of the first Optical Gain Block 510 and second Optical Gain Block 520) then the Tx 500 acts as a ECL at the wavelength(s) of the third Reflector 540 and fourth Reflector 550.

Similarly, if the third Reflector 540 and fourth Reflector 550 are high reflectivity mirrors and the first Reflector 515 and second Reflector 525 are wavelength selective reflectors then the Tx 500 acts as a ECL at the wavelength(s) of the first Reflector 515 and second Reflector 525. In this embodiment of the invention where the Tx 550 is fixed in operating wavelength each of the first Reflector 515 and second Reflector 525 may be a Bragg reflector wherein by appropriate design of a PIC the Bragg reflectors to provide the first Reflector 515 and second Reflector 525 may be aligned in wavelength as they employ a common grating structure.

Within another embodiment of the invention the 2×2 Coupler 530 may be a 1×2 coupler such that the port 500B is now non-existent and similarly the second Optical Gain Block 520 and second Reflector 525 are not present. If each of the third Reflector 540 and fourth Reflector 550 are wavelength selective reflectors each with a defined and different free spectral ranges (FSR) then the resulting gain profile is established through the combination of the optically resonant paths from first Reflector 515 to each of the third Reflector 540 and fourth Reflector 550 respectively wherein emission of the Tx 500 will occur at the wavelength where the reflectivity of third Reflector 540 and fourth Reflector 550 align. In this manner, through tuning of one or both of the third Reflector 540 and fourth Reflector 550 the Tx 500 may emit at one wavelength defined by the vernier overlay of the periodic wavelength response defined by the FSR of the third Reflector 540 and the other periodic wavelength response defined by the FSR of the fourth Reflector 550. In addition to thermal tuning elements for the third Reflector 540 and fourth Reflector 550 one or more optical phase shifters may be provided within the Tx 500 to ensure that the optical paths from the first Reflector 515 to each of the third Reflector 540 and fourth Reflector 550 respectively have a predetermined phase relationship between them, e.g. same phase.

Phase shifting elements to correct for phase misalignments in the optical paths arising from manufacturing variations of Tx 550 have been omitted for the sake of clarity.

Alternatively, within another embodiment of the invention one of the third Reflector 540 and fourth Reflector 550 may be a broadband reflector with or without a monitoring photodetector. Accordingly, in these configurations optical lasing outputs are obtained from first Port 500A and second Port 500B whilst no optical emission or only noise/spontaneous emission are at the third Port 500C and fourth Port 500D.

Alternatively, first Reflector 515 is high reflectance reflector with first optical gain block 510 whilst second Reflector 525 is a wavelength selective high reflectance reflector in conjunction with second Optical Gain Block 520. Each of the third Optical Gain Block 540 and fourth Optical Gain Block 550 are optical gain blocks with high reflectivity mirrors such that Tx 500 acts as a dual output source with wavelength selective outputs on third and fourth Ports 500C and 500D respectively.

2×2 Coupler 530 may be a directional coupler, an X-junction, a 2×2 Mach-Zehnder Interferometer (MZI), a zero gap directional coupler or a multi-mode interference (MMI) coupler (MMI). Optionally, 2×2 Coupler 530 may include additional wavelength filtering. Within these embodiments integration may be monolithically integrated and/or hybridly integrated. Within hybrid integration methodologies, structures such as PWBs, micro-lenses, direct written micro-lenses, butt-coupling etc. may be employed.

Within embodiments of the invention the upper left portion comprising first Reflector 515 and first optical gain block 510 may be equivalent to second Optical Block 300B in FIG. 3 whilst the lower left portion comprising second Reflector 525 and second optical gain block 520 may be equivalent to third Optical Block 300C in FIG. 3. Accordingly, one of or both of third optical gain block 540 and fourth optical gain block 550 may be equivalent to first Optical Block 300A in FIG. 3. Accordingly, the Tx 500 has a pair of optical outputs that are wavelength locked with respect to each other.

Within other embodiments of the invention, the upper left portion comprising first Reflector 515 and first Optical Gain Block 510 may be equivalent to second PWB 260, first Low Reflectivity Facet Coating 270, and first Semiconductor Gain Block 280—as depicted in FIG. 2. The lower left portion comprising second Reflector 525 and second optical gain block 520 may be equivalent to the third PWB 265, second Low Reflectivity Facet Coating 275, second Semiconductor Gain Block 285, as depicted in FIG. 2. Accordingly, one of or both of third Optical Gain Block 540 and fourth Optical Gain Block 550 may be equivalent to MPD 210, silicon nitride facet 220, SiN PIC 230 and PWB 240 as depicted in FIG. 2. Accordingly, the Tx 500 has a pair of optical outputs which are coupled emitters with common wavelength.

Now referring to FIG. 6 there is depicted a generalized functional schematic of an optical transmitter (Tx) 600 according to an embodiment of the invention. The optical structure of Tx 600 may be according to one of the embodiments of the invention as described above with respect to Tx 500 in FIG. 5. However, disposed in the path between the 2×2 Coupler 530 and first Port 500A is first Optical Element 610 and within the path between the 2×2 Coupler 530 and second Port 500B is second Optical Element 620. Each of the first Optical Element 610 and second Optical Element 620 may be an optical phase shifter allowing the optical paths to be balanced within Tx 600. Alternatively, only one of the first Optical Element 610 and second Optical Element 620 may provide polarization rotation such that first Optical Gain Block 510 and second Optical Gain Block 520 of the Tx 600 are emitting at a common wavelength but upon TE and TM polarizations whilst the 2×2 Coupler 530 and functional elements to the right of it in the schematic are all operating upon only one polarization. Optionally, the third Optical Gain Block 540 and fourth Optical Gain Block 550 are wavelength reflectors with or without optical gain which are offset relative to one another by a predetermined offset such that the Tx 600 emits on each port dual wavelengths. In some embodiments of the invention these may be offset by a predetermined frequency for self-mixed clock generation at a receiver.

Within another embodiment of the invention first Optical Element 610 and second Optical Element 620 may polarisation filters, for first and second polarisations respectively, where the first Optical Gain Block 510 and second Optical Gain Block 520 respectively operate upon the first and second polarisations respectively. With a polarisation independent 2×2 Coupler 530 and polarisation independent third Optical Gain Block 540 and fourth Optical Gain Block 550 the Tx 600 operates a laser with dual output polarisations. With one or more fixed or variable wavelength filters disposed within the Tx 600, e.g. with a PIC combining these with 2×2 Coupler 530 these two polarisations are at the same wavelength.

Within another embodiment of the invention all elements within Tx 600 operate upon a single polarisation with first Optical Element 610 and second Optical Element 620 being phase shifters and/or wavelength filters and a polarisation rotator is implemented on either the first Port 500A (or between the first Port 500A and first Reflector 515) or the second Port 500B (or between the second Port 500B and the second Reflector 525). Accordingly, the Tx 600 provides dual outputs at the same wavelength but each with a different polarisation.

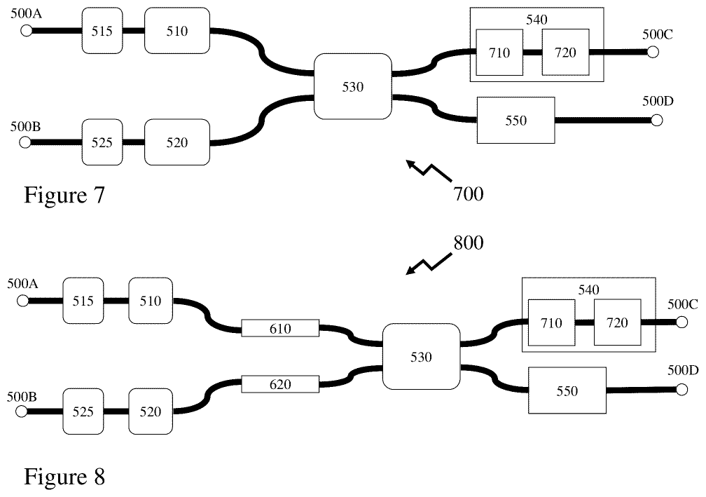

Referring to FIG. 7 there is depicted a generalized functional schematic of an optical transmitter (Tx) 700 according to an embodiment of the invention. Overall the functionality of Tx 700 is similar to the embodiments of the invention described above with respect to FIGS. 5 and 6. However, third Optical Gain Block 540 is now depicted as comprising first Optical Element 710 and second Optical Element 720 where first Optical Element 710 is a tunable filter and second Optical Element 720 a high reflectivity mirror with monitoring photodiode. Accordingly, the Tx 700 can be tuned to a different emitting wavelength rather than being either fixed by a fixed filter (e.g. Bragg grating) or limiting tuning (e.g. thermo-optic tuning of Bragg grating). Alternatively, first Optical Element 710 is a wavelength locker and second Optical Element 720 a monitoring photodiode disposed after a high reflectivity filter, not depicted for clarity.

Now referring to FIG. 8 there is depicted a generalized functional schematic of an optical transmitter (Tx) 800 according to an embodiment of the invention which comprises a configuration as depicted for Tx 700 in FIG. 7 but with the addition of first Optical Element 610 and second Optical Element 620 as described above in respect of FIG. 6.

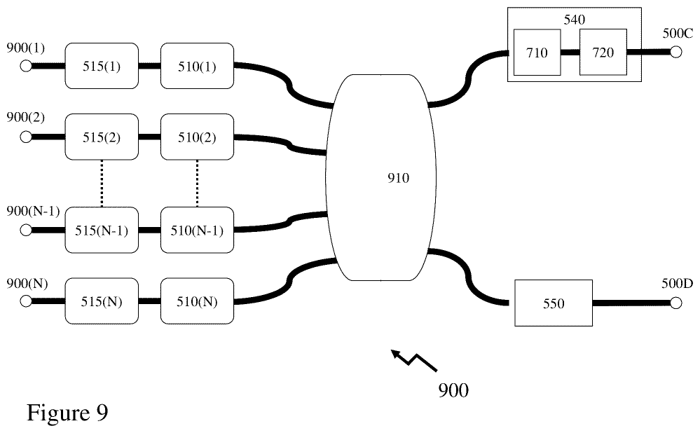

Referring to FIG. 9 there is depicted a generalized functional schematic of an optical transmitter (Tx) 900 according to an embodiment of the invention where the overall structure is similar to that depicted in FIG. 7 except that the 2×2 Coupler 530 is now a N×2 Coupler 910 such that rather than two paths on the left hand side there are now N parallel paths such that there are N first Reflectors 515(1) to 515(N) which are high reflectance reflectors and N Optical Gain Blocks 510(1) to 510(N).

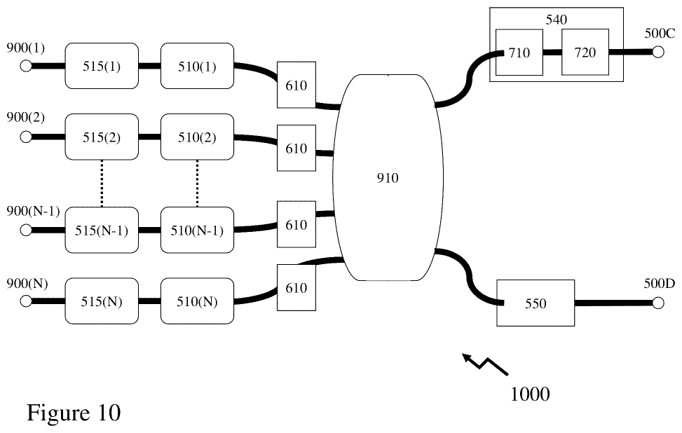

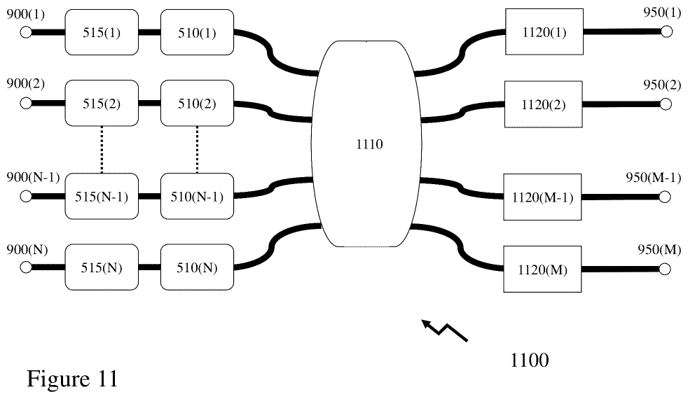

FIG. 10 depicts a generalized functional schematic of an optical transmitter (Tx) 1000 according to an embodiment of the invention according to an embodiment of the invention where the overall structure is similar to that depicted in FIG. 8 except that the 2×2 Coupler 530 is now a N×2 Coupler 910 such that rather than two paths on the left hand side there are now N parallel paths with outputs 900(1) to 900(N) such that there are N first Reflectors 515(1) to 515(N) which are high reflectance reflectors and N Optical Gain Blocks 510(1) to 510(N).

It would be evident that the right hand side of FIGS. 9 and 10 may be similarly generalized as depicted in FIG. 11 with Tx 1100 wherein central coupler is now a N×M Coupler 1110. As with FIG. 10 on the left hand side of Tx 1100 there are N parallel paths from the N×M Coupler 1110 to first Ports 900(1) to 900(N) each comprising a first Reflector and an Optical Gain Block such that there are N first Reflectors 515(1) to 515(N) and N Optical Gain Blocks 510(1) to 510(N) coupled to the N×M Coupler 1110. On the right hand side of Tx 1100 there are M Optical Blocks 1120(1) to 1120(M) disposed upon the M paths from the N×M Coupler 1110 to the M other Ports 950(1) to 950(M) respectively.

Within an embodiment of the invention each of the M Optical Blocks 1120(1) to 1120(M) comprised an optical reflector wherein one of the M Optical Blocks 1120(1) to 1120(M) may be a fixed or wavelength tunable reflector such that the Tx 1100 provides multiple optical outputs all at the same wavelength defined by the fixed or wavelength tunable reflector. Alternatively, the fixed or wavelength tunable reflector may be implemented as one of the N first Reflectors 515(1) to 515(N).

Within another embodiment of the invention R Optical Blocks of the M Optical Blocks 1120(1) to 1120(M) may be a fixed or wavelength tunable reflector such that the Tx 1100 provides multiple optical outputs at the wavelengths defined by the fixed or wavelength tunable reflectors within the R Optical Blocks. Alternatively, the multiple fixed or wavelength tunable reflectors may be implemented within a subset of the N first Reflectors 515(1) to 515(N).

In each instance a fixed wavelength selective reflector may comprise a single Bragg reflector to generate multiple outputs locked to the same wavelength or it may comprise multiple Bragg reflectors such that it generates multiple outputs each with multiple wavelengths (e.g. optical wavelength combs). Where there are R Optical Blocks each incorporating S Bragg reflectors then the Tx 1100 provides multiple outputs each comprising R×S wavelengths.

Within another embodiment of the invention the N×M Coupler 1110 is replaced with an N×1 optical switch and 1×M splitter such that the Tx 1100 operates upon only wavelength but the output wavelength is set by the N×1 optical switch selecting the desired wavelength dependent reflector on one arm of the left hand side of FIG. 11. In this manner, the desired wavelength switching speed of the Tx 1100 is defined by the switching speed of the N×1 switch rather than the tuning speed of the wavelength dependent reflectors. Accordingly, in some instances under network control the Tx 1100 may pre-set the next wavelength on a different wavelength dependent reflector to that currently defining the wavelength(s) of the Tx 1100 and then switch to it. It would be evident that other embodiments of the invention with N×T optical switch and TxM splitter would allow the Tx to select T wavelength dependent reflectors such that T wavelengths of the Tx 1100 are dynamically configurable with fixed wavelength dependent reflectors or slow reconfigurable wavelength dependent reflectors.

Within the ECL structures described and depicted in respect of FIGS. 1 to 11 a non-linear saturable absorber may be integrated within the structure such that the ECL rather than a CW source is now a pulsed source with optical characteristics defined by the overall ECL design and the characteristics of the non-linear saturable absorber. Alternatively, the ECL may include a modulator structure within other embodiments of the invention.

Within embodiments of the invention a wavelength filter defining the emitting wavelength of an optical source may be fixed, tunable or settable to one or more predetermined wavelengths. Within embodiments of the invention a settable wavelength reflector may employ multiple Bragg gratings such as depicted in FIG. 12 wherein a Switchable 8 Wavelength Filter 1200 is depicted. As depicted a 1×8 Switch 1210 employing a cascade of 1×2 switches in three ranks with first Switch 1220A in the first rank, second and third Switches 1230A and 1230B in the second rank, and fourth to seventh Switches 1240A to 1240D respectively in the third rank. The outputs from the 1×8 Switch 1210 are each coupled via first to eighth Gates 1250A to 1250H respectively to first to eighth Wavelength Selective Reflective Filters 1260A to 1260H respectively. Accordingly, the first to eighth Gates 1250A to 1250H respectively increase the isolation of the 1×8 Switch 1210 with respect to selecting the one of the first to eighth Wavelength Selective Reflective Filters 1260A to 1260H respectively. Accordingly, the Switchable 8 Wavelength Filter 1200 allows a transmitter according to an embodiment of the invention to switch between each wavelength of the 8 waveguides defined by the first to eighth Wavelength Selective Reflective Filters 1260A to 1260H respectively.

Optionally, a Wavelength Selective Reflective Filter of the first to eighth Wavelength Selective Reflective Filters 1260A to 1260H respectively may provide reflection of two or more wavelengths rather than a single wavelength.

It would be evident that the Switchable 8 Wavelength Filter 1200 can be generalised to a Switchable N Wavelength Filter where N is a positive integer equal to or greater than 2. A Switchable N Wavelength Filter may provide switching to channels on a defined grid, e.g. 25 GHz, 50 GHz, 100 GHz, 200 GHz, etc. or channels on another grid, e.g. CWDM.

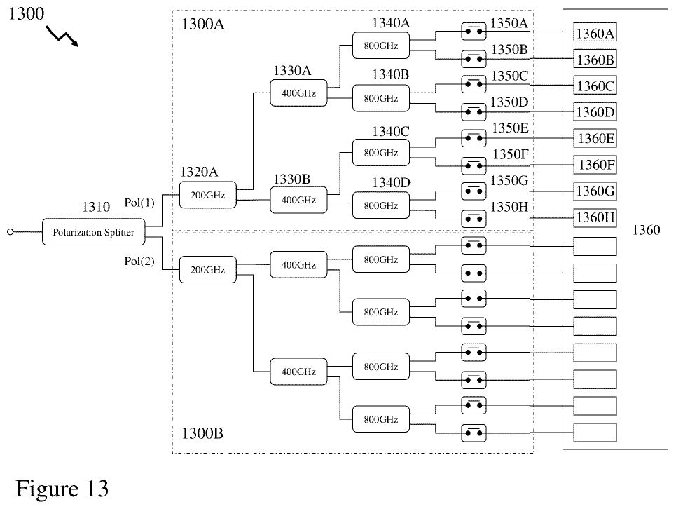

Referring to FIG. 13 there is depicted an exemplary Switchable Wavelength Optical Transmitter Filter (SWOTF) circuit 1300A exploiting cascaded deinterleaving and optical switching (D-INT) to band select prior to a Wavelength Selective Reflector Array (WSRA) 1360. The SWOTF 1300 represents a polarisation independent SWOTF whereas within embodiments of the invention where the SWOTF is integrated into an ECL, the SWOTF may simply be required to operate upon a single polarisation. Accordingly, in such an embodiment only one of a first D-INT-Switch 1300A or a second D-INT-Switch 1300B would be required.

As depicted the SWOTF 1300 comprises a Polarization Splitter 1310, the first D-INT-Switch 1300A, the second D-INT-Switch 1300B and a Wavelength Selective Reflector Array (WSRA) 1360. Polarization Splitter 1310 receives the optical signals and generates a pair of output signals, the upper, denoted as Pol(1), is coupled to the first D-INT-Switch 1300A and the lower, denoted as Pol(2), is coupled to the second D-INT-Switch 1300B. For example, Pol(1) may be transverse electric (TE) and Pol(2) transverse magnetic (TM) or vice-versa. It would be evident to one skilled in the art that additional embodiments of the SWOTF 1300 are possible, for example, according to a polarisation insensitive operation without a polarization splitter 1310 and by replacing the polarization splitter 1310 with a polarization splitter rotator and having both D-INT-Switch 1310A operate according to the fundamental mode (e.g. TE0) and D-INT-Switch 1300B operate according to the first order odd mode (e.g. TE1) both of a common polarisation (i.e. the Transverse Electric polarisation).

An exemplary reference use case of a SWOTF applies to a passive optical network broadcasting through an optical power splitter (typically a 1:32), four or eight wavelengths on the ITU Grid spaced apart according to the 100 GHz channel spacing, referring to the ITU-T G.989.2 standard (NG-PON2) in the L-band, where the SWOTF would be tasked to select one or more of the following channels: 187.8, 187.7, 187.6, 187.5, 187.4, 187.3, 187.2 and 187.1 THz. It would be evident to one skilled in the art that other channel spacings, channel counts, etc., are possible such as, for example, those identified in the IEEE 802.3cn-2019 standard for 400GBASE-FR8, LR8 and ER8 in the O-band. In this instance, a SWOTF would select one or a few channels among the following channels on an 800 GHz grid with channels at 235.4, 234.6, 233.8, 233, 231.4, 230.6, 229.8 and 229 THz. Further, embodiments of the invention can support selection of one or more channels from WDM streams based upon specifications providing 16, 32, 48 or 96 channels spaced apart by 50 GHz, 100 GHz, 400 GHz or 800 GHz respectively, or even spaced apart by as much as 20 nm as would be the case, for example, with CWDM4 or CWDM8.

Now referring to FIG. 13, a SWOTF 1300 applicable to the reference use case of an optical network terminal receiver for the NG-PON2 standard is depicted supporting selection of one channel from 8 channels upon a 100 GHz channel spacing. The SWOTF 1300, according to an embodiment of the invention employing a 3-stage cascade of Mach-Zehnder Deinterleavers (D-INT) with progressively doubling free spectral range (FSR) at each stage. The incoming stream is initially coupled to a Polarization Management Device 1310 which provides a first output with a first polarisation, Pol(1), and a second output with a second polarisation, Pol(2). The first output of a Polarization Management Splitter 1310 is connected to a 200 GHZ FSR D-INT which forms the first stage 1320A. Each of its outputs is one of two instances of a 400 GHz FSR D-INT in the second stage formed by first and second 400 GHz D-INT FSR 1330A and 1330B. In the second stage, each one of the first and second 400 GHZ FSR D-INTs 1330A and 1330B are each connected to a pair of 800 GHz FSR D-INTs forming the third and final stage, which thereby comprises first to fourth 800 GHZ D-INTs 1340A, 1340B, 1340C and 1340D respectively. Each of the first to fourth 800 GHZ D-INTs 1340A-1340D respectively has two outputs, thus collectively totaling 8 outputs, with a one to one correlation between an output and a channel of the 8 channels coupled to the SWOTF 1300 with the Pol(1) polarisation. This upper D-INT-Switch 1300A of seven instances of D-INTs is replicated a second time as lower cascade 1300B, this time operating upon the other polarisation from the Polarisation Splitter 1310, Pol(2). SWOTF 1300 therefore comprises a total of 14 D-INTs. Each of the outputs from the first to fourth 800 GHZ D-INTs 1340A, 1340B, 1340C and 1340D respectively in each of the upper D-INT-Switch 1300A and lower D-INT-Switch 1300B are coupled to an optical gate (on-off switch) 1350A to 1350H within D-INT-Switch 1300A and equivalent optical gates (unnumbered) within D-INT-Switch-1300B. The output of each of these optical gates are routed to a Wavelength Selective Reflector (WSR) of the first to eighth WSRs 1360A to 1360H respectively. Selection of a given channel is performed by keeping all optical gates in the off-state except for those relating to the output(s) from the third stage of upper cascade 1300A and lower D-INT-Switch 1300B which correspond to the desired channel. Accordingly, the optical signals coupled to the input port of the SWOTF 1300 are selectively reflected by the selected WSR of the first to eighth WSRs 1360A to 1360H respectively wherein the ECL within which the SWOTF 1300 is integrated then emits upon the wavelength range defined by the selected WSR of the first to eighth WSRs 1360A to 1360H respectively.

The detailed embodiment of SWOTF 1300 is as follows. First D-INT-Switch 1300A comprising a 200 GHz free spectral range (FSR) D-INT 1320A is coupled to first 400 GHz FSR D-INT 1330A and second 400 GHz FSR D-INT 1330B. The first 400 GHz FSR D-INT 1330A is coupled to first and second 800 GHz FSR D-INTs 1340A and 1340B respectively whilst second 400 GHZ FSR D-INT 1330B is coupled to third and fourth 800 GHZ FSR D-INTs 1340C and 1340D respectively. The first 800 GHZ FSR D-INT 1340A being coupled to WSR 1360 via first and second optical gates (OGs) 1350A and 1350B respectively, the second 800 GHz FSR D-INT 1340B being coupled to WSR 1360 via third and fourth OGs 1350C and 1350D respectively, third 800 GHz FSR D-INT 1340C being coupled to WSR 1360 via fifth and sixth OGs 1350E and 1350F respectively, and fourth 800 GHz FSR D-INT 1340D being coupled to WSR 1360 via seventh and eighth OGs 1350A and 1350B respectively. In this embodiment, the optical gates (OGs) behave as ON-OFF optical switches.

Within an embodiment of the invention the OGs may be implemented normally-OFF and activated to be in the ON state. Accordingly, only one switch is required to be driven in each of the first D-INT-Switch 1300A and second D-INT-Switch 1300B respectively, to commonly select one channel.

Second D-INT-Switch 1300B has a similar structure but operates upon the optical signals having polarisation Pol(2) whereas first D-INT-Switch 1300A operates upon the optical signals having polarisation Pol(1). Accordingly, considering an input optical signal comprising 8 wavelengths on a 100 GHz grid, W1, W2, W3, W4, W5, W6, W7 and W8 then that component of these optical signals having polarisation Pol(1) at the SWOTF 1300 are routed to first D-INT-Switch 1300A whilst the remaining component having polarisation Pol(2) are routed to the second D-INT-Switch 1300B. Within the following description the operation of first D-INT-Switch 1300A only is described for brevity as the operation of second D-INT-Switch 1300B is the same.

At the 200 GHz FSR D-INT 1320A stage, channels W1, W3, W5 and W7 are routed to first 400 GHZ FSR D-INT 1330A whilst channels W2, W4, W6 and W8 are routed to second 400 GHZ FSR D-INT 1330B. First 400 GHZ FSR D-INT 1330A then routes channels W1, W3, W5 and W7 such that W1 and W5 are routed to first 800 GHZ FSR D-INT 1340A whilst W3 and W7 are routed to second 800 GHZ FSR D-INT 1340B. First 800 GHZ FSR D-INT 1340A then routes channel W1 to first OG 1350A and channel W5 to second OG 1350B whilst second 800 GHZ FSR D-INT 1340B then routes channel W3 to third OG 1350A and channel W7 to fourth OG 1350D.

Similarly, second 400 GHZ FSR D-INT 1330B then routes channels W2, W4, W6 and W8 such that W2 and W6 are routed to third 800 GHZ FSR D-INT 1340C whilst W4 and W8 are routed to fourth 800 GHZ FSR D-INT 1340D. Third 800 GHZ FSR D-INT 1340C then routes channel W2 to fifth OG 1350E and channel W6 to sixth OG 1350F whilst fourth 800 GHZ FSR D-INT 1340D then routes channel W4 to seventh OG 1350G and channel W8 to eighth OG 1350H.

If the first to eighth OGs 1350A to 1350H are “open” then no optical signals are coupled to the WSRA 1360. Accordingly, “closing” one of the first to eighth OGs 1350A to 1350H couples its associated wavelength, being W1, W5, W3, W7, W2, W6, W4, W8 respectively, to the WSR 1360. These optical signals being at Pol(1). Operating the associated OG within the second D-INT-Switch 1300B couples the optical signals at the same channel with the other polarisation Pol(2) to the WSRA 1360 wherein the WSRA 1360 combines the optical signals from both polarisations. Accordingly, the SWOTF 1300 acts as a polarisation independent switched wavelength optical receiver which is capable of selecting one of 8 wavelengths (or wavelength bands) whilst the first and second D-INT-Switches 1300A and 1300B are polarisation dependent D-INTs with optical gates.

Within the structure depicted in FIG. 13 the 200 GHZ FSR D-INT 1320A, first 400 GHZ FSR D-INT 1330A and second 400 GHZ FSR D-INT 1330B operate as cyclic deinterleavers. It would be evident that alternate architectures may be employed for the D-INT portion using integrated optics band filters etc. such that the wavelengths are separated in a different sequence, e.g. W1-W4 from W5-W8 initially, but such bandpass filters are very challenging to fabricate in integrated optics owing the lack of a guard band between W4 and W5. Platforms such as silicon photonics can take advantage of the cyclic property of Mach-Zehnder Interferometer in a cascade of Mach-Zehnder deinterleavers (D-INT) with free spectral ranges aligned to the spacing (e.g. 100 GHz) between the channels to select from. Accordingly, the architecture depicted is suited to monolithic integration where all functionality is integrated onto the same photonic integrated circuit (PIC).

It would be evident that the SWOTF 1300 can be expanded to include fourth, fifth, sixth stages etc. such that the SWOTF 1300 operates upon 16, 32, 64, etc. channels. Similarly the FSR of the D-INTs within each stage of an 8-channel SWOTF 1300 with a 50 GHz channel spacing, may be 100 GHz, 200 GHz and 400 GHz. The same SWOTF 1300 with a 50 GHz channel spacing could be extended to 16 channels by adding an additional D-INT stage with an 800 GHz FSR and further extended to 32 channels by adding yet another stage with an FSR of 1.6 THz etc. Alternatively, the first stage D-INTs may operate 50 GHz or 400 GHz with subsequent stages doubling in FSR for supporting other grid plans. Similarly, operation of the SWOTF 1300 may be solely in a single telecommunications band, such as O-band, E-band, S-band, C-band, and L-band for example or span two more telecommunications bands such as C-band and L-band for example.

Whilst a reverse frequency sequence may be implemented within a PIC starting with an initial 800 GHZ FSR D-INT in each of the first and second Switch-D-INT 1300A and 1300B and ending with multiple 200 GHZ FSR D-INTs this is generally not employed as it would require many instances of the D-INTs with smaller FSR and thus many components of the largest size and highest fabrication tolerance requirements, thereby impacting die yield and costs. Accordingly, the architecture in FIG. 13 has higher numbers of the lower tolerance components (e.g. 800 GHZ FSR D-INTs) than higher tolerance components (e.g. 200 GHz FSR D-INTs).

The WSR 1360 may be hybridly integrated, monolithically integrated, or an external component coupled to the outputs of the array of optical gates via PIC waveguides, PIC waveguide facets, optical fibers, optical fiber ribbon(s), photonic wirebonds, etc. WSRA 1360 may, for example, be a reverse biased p-i-n diode or an avalanche photodiode.

Accordingly, it would be advantageous to reduce the size of the “tree” of D-INTs to reduce the size of the SWOTF overall, reduce the number of waveguides converging on the high-speed photodetector, and reduce the number of D-INTs required thereby reducing die dimensions. In FIG. 4A, the inventors have pioneered the concept of implementing optical switching between deinterleaving stages of a SWOTF by way of an additional instance of a balanced MZI used as a 2×2 optical switch. In FIG. 4B, the inventors have pioneered the concept of introducing an integrated-optics micro-electro-mechanical-system (IO-MEMS) 2×1 optical switch between the D-INT stages within the “tree”, especially at the output of the D-INT with the smallest FSR, which segregates odd from even channels to maximize the adjacent channel isolation (which contributes most to the crosstalk penalty of a system with few channels) owing to the non-interferometric behaviour of an IO-MEMS 2×1 optical switch, which thus has inherently superior wavelength extinction ratio over a balanced MZI switch.

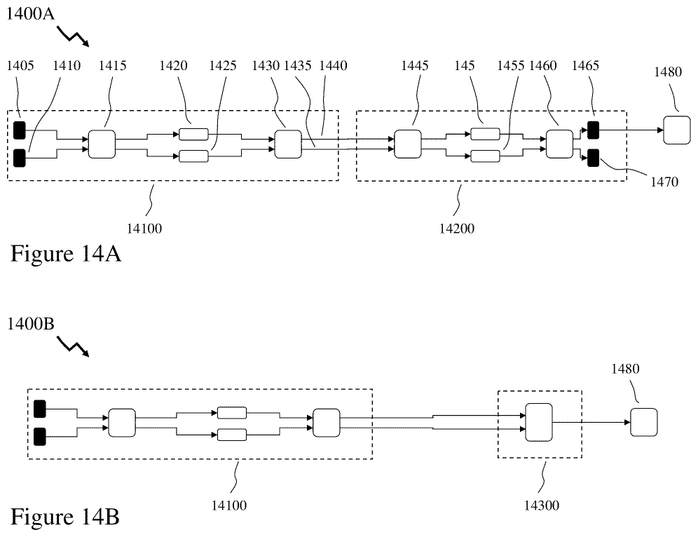

Now referring to FIG. 14A a SWOTF based on a cascade of D-INT with external Optical Selector (OS) is depicted in respect of a SWOTF 1400A employing a cascade of Mach-Zehnder deinterleavers with optical switching circuits between the stages. Accordingly, the D-INT-Switch 1400A comprises a cascade of Mach-Zehnder deinterleavers 14100 in series with a PIC Switch 14200. The PIC switch 14200 is made from an unbalanced MZI and has a response that is more wavelength insensitive than engineering a cross or bar stage inside an unbalanced MZI, such as being the case within the D-INT Switches, thus enhancing the wavelength extinction ratio at each stage of the SWOTF. However this comes at the expense of increasing the PIC footprint and the number of MZIs. As examples, PIC switch may be inserted between the 1^{st} stage and the 2^{nd} stage only of a four-channel SWOTF or between both the first stage and the second stage as well as between the second stage and the third stage in the case of an 8-channel SWOTF. As depicted the cascade of Mach-Zehnder deinterleavers 14100 comprises a first input 1405, second input 1410, input coupler 1415, upper arm 1420, lower arm 1425 and output coupler 1430 providing first and second outputs 1435 and 1440 respectively. Accordingly, the input coupler 1415 and output coupler 1430 are 50:50 couplers, such as 2×2 multimode interference (MMI) couplers or 2×2 directional couplers wherein a path imbalance is provided between the upper arm 1420 and lower arm 1425 connecting the input coupler 1415 to the output coupler 1430. Within FIGS. 14A and 14B the D-INT is a photonic circuit element based upon an unbalanced Mach-Zehnder interferometer wherein either arm are both arms are employed for bias adjustment, without seeking to deliberately flip the output ports of 14100, leaving it to PIC switch 14200 to do so.

It is noted that in the case of Figure that there is no need to have both output coupler 1430 and input coupler 1445 as it would be possible to connect the outputs 1435 and 1440 of the first D-INT directly to the two arms of the PIC switch 14200, thus bypassing its input or 2×2 coupler 1445. The path imbalance is established according to the FSR of each stage in the cascade of Mach-Zehnder deinterleavers 14100. The result is that wavelengths are deinterleaved according to the FSR of each stage in the cascade of Mach-Zehnder deinterleavers 14100 to a first stream upon first output 1435 and a second stream upon second output 1440.

For example, if D-INT-Switch 1400A has an FSR of 200 GHz and receives channels L(1) to L(8) on a 100 GHz channel spacing then wavelengths L(S) where S=1, 3, 5, 7 are coupled to the first output 1435 and the remaining wavelengths L (T) where T=2, 4, 6, 8 are coupled to the second output 1440. The first and second outputs 1435 and 1440 are then coupled to PIC Switch 14200 which comprises a balanced Mach-Zehnder interferometer with first coupler 1445 and second coupler 1460 together with first arm 1450 and second arm 1455 yielding third output 1465 and fourth output 1470. The third output 1465 being coupled to subsequent Optical Circuit 1480 which may, for example, be another D-INT-Switch 1400A with different FSR or a Wavelength Selective Reflective Filter forming Optical Circuit 1480 in FIGS. 14A and 14B. Accordingly, first coupler 1445 and second coupler 1460 are 50:50 couplers, such as 2×2 multimode interference (MMI) couplers or 2×2 directional couplers, wherein establishing the appropriate phase imbalance between the first arm 1450 and second arm 1455 routes either the optical signals upon the first out 1435 of the cascade of Mach-Zehnder deinterleavers 14100 to the third output 1465 or the optical signals upon the second output 1440 of the cascade of Mach-Zehnder deinterleavers 14100 to the third output 1465. In either instance the signals on the other output from the cascade of Mach-Zehnder deinterleavers 14100 are routed to fourth output 1465. Accordingly, by appropriately setting the relative phase bias between the first arm 1450 and the second arm 1455 the PIC Switch 14200, though a 2×2, acts a 2×1 switch routing the appropriate output from the cascade of Mach-Zehnder deinterleavers 14100 to the Optical Circuit 1480. Optionally, the signal recovered on output port 1470 may be sent to a monitoring photodetector (not show) for purposes of facilitating circuit calibration, monitoring and configuration.

Optionally, PIC Switch 14200 may be an unbalanced Mach-Zehnder interferometer rather than a balanced Mach-Zehnder interferometer. Optionally PIC Switch 14200 may a 2×1 directional coupler switch, a 2×1 digital optical Y-branch switch, or other PIC based optical switch.

Accordingly, D-INT-Switch 1400A may be cascaded with different FSRs for the Mach-Zehnder deinterleavers 14100 to provide the multi-stage D-INT Switches as described and depicted in FIGS. 14A and 14B respectively.

Now referring to FIG. 14B there is depicted an exemplary D-INT-Switch 1400B comprising cascade of Mach-Zehnder deinterleavers 14100 with 2×1 microelectromechanical systems (MEMS) switch 14300 to select the appropriate output from the cascade of Mach-Zehnder deinterleavers 14100 to route to the Optical Circuit 1480. The MEMS switch may employ a microoptoelectromechanical systems (MOEMS) such as described by the inventors within U.S. Pat. No. 10,466,421 entitled “Methods and System for Wavelength Tunable Optical Components and Sub-Systems”, U.S. Pat. No. 10,694,268 entitled “Photonic Switches, Photonic Switching Fabrics and Methods for Data Centers”, and World Patent Application PCT/CA2019/000,156 entitled “Structures and Methods for Stress and Gap Mitigation in Integrated Optics Microelectromechanical Systems.” The entire contents of these patents and patent specifications being incorporated herein by reference.

A benefit of using a MEMS switch 14300 relative to PIC Switch 14200 may be obtained within some system environments where the wavelength range is broad as the MEMS Switch 14300 is inherently broadband relative to interference based PIC Switches 14200, e.g. Mach-Zehnder interferometer or directional coupler based switches, where there is a wavelength dependence to these within the band of interest. This is particularly important for the D-INT-Switch with the lowest FSR as it has the highest impact of the adjacent channel isolation and the associated crosstalk penalty this introduces. Accordingly, in some embodiments of the invention with a D-INT-Switch comprising a cascade of deinterleaver instances a portion of them, for example those with lower FSRs, may employ MEMS based WSOS such as depicted within D-INT-Switch 1400B in FIG. 14B whilst another portion of the, for example those with higher FSRs, may employ PIC Switch based D-INT Switches such as depicted within D-INT-Switch 1400A in FIG. 14B. In other embodiments all WSOS may be one design, e.g. D-INT-Switch 1400A or D-INT-Switch 1400B.

Nonetheless, the previous embodiments described in FIGS. 14A and 14B where the optical switching function is external to the D-INTs exhibit a drawback of increased PIC footprint of the complete SWOTF and the inventors have subsequently focused their attention searching how to attain as good performance as with D-INTs paired with external optical switches, by way of introducing the concept of a wavelength selective optical switch (WSOS) in which optical switching function is embedded inside the D-INTs. WSOS structures and SWOTFs employing them are described below with respect to FIGS. 5A to 8 respectively.

The inventors have established using silicon nitride as a material for waveguide core can provide a lower effective index and an increased delocalized mode compared to silicon waveguides thereby providing increased resilience to random phase noise introduced by random variation in the micro-fabrication process when exploiting high-efficiency thermo-optic phase shifters.

The inventors note that whilst the D-INTs described within embodiments of the invention are explicitly or implicitly combined with thermo-optic or thermo-mechanical-optic phase shifters, these are primarily to compensate for fabrication imperfection and not to make use of them for purposes of doubling the free spectral range of the D-INT. Within other embodiments of the invention phase shifters may be implemented though other means other than thermo-optic according to the optical waveguide technology. Such means may include, for example, electro-optic, magneto-optic, physical path adjustment through MEMS for example, or refractive index adjustment through adjustment of the waveguide structure. Adjustment of the waveguide structure being, for example, by MEMS based actuation of an element disposed close to the core of optical waveguide.

Within an embodiment of the invention a Wavelength Selective Reflective Filter (WSRF) forming Optical Circuit 1480 may comprise a linear array of Bragg grating reflectors (BGR), for example, integrated into a waveguide with a subset of the linear array of BGRs being associated with each FSR of the WSOS circuit deployed in front. For example, the WSOS circuit may be cascaded to select one FSR of 16 potential FSRs with a BGR associated with each FSR such that the WSOS with the Optical Circuit 1480 provides a wavelength settable reflective filter for 16 discrete wavelengths each associated with a BGR of the linear array of BGRs. Within another embodiment of the invention the BGR may be a cyclic BGR with an FSR equal to that of the WSOS cascade such that the WSOS selects a FSR of multiple FSRs and the cyclic BGR forming the WSRF of the Optical Circuit 1480 defines the exact spectral characteristics of the reflected signals, e.g. exact frequency, bandwidth, passband shape etc. Within other embodiments of the invention the WSRF within the Optical Circuit 1480 may be a micro-optical Fabry-Perot resonant filter for example or other micro-optical filter structure providing either a cyclic wavelength response or employing multiple filters each tailored to one or more FSR of the multiple FSRs supported by the WSOS. Within a cyclic reflector and WSOS cascade a low complexity wavelength settable filter for multiple wavelengths can be formed and integrated into an ECL according to an embodiment of the invention to provide a wavelength settable ECL.

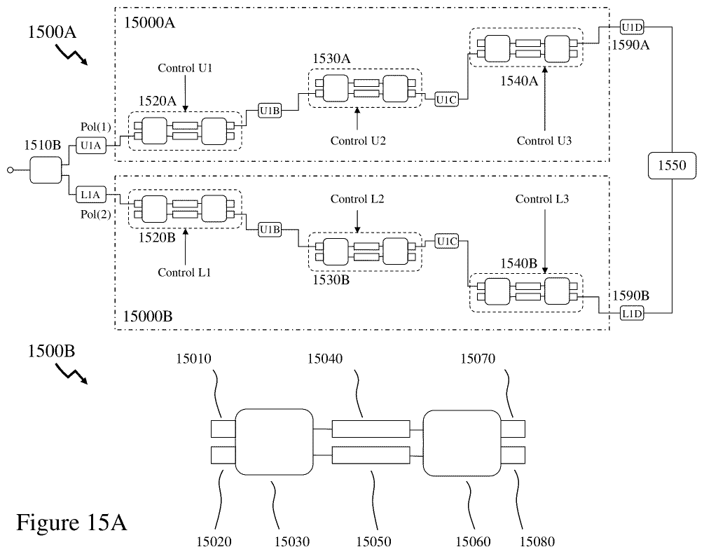

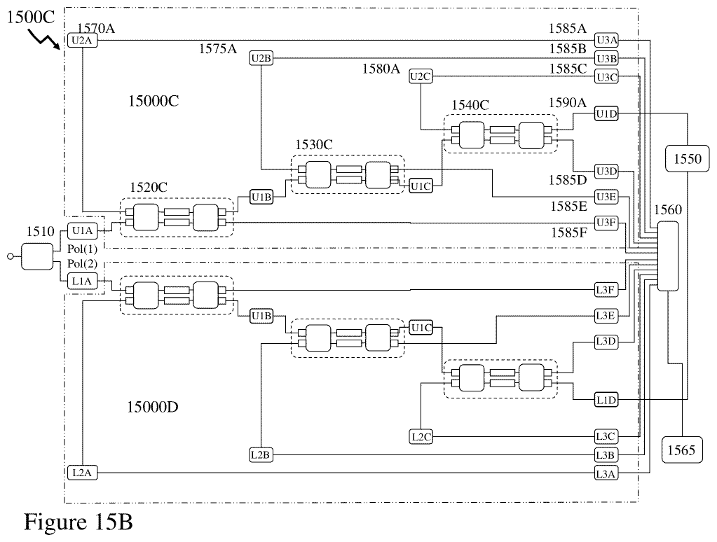

In FIG. 15, the Inventors describe an embodiment of the invention with respect to a wavelength selective optical switch (WSOS), making it possible to reduce the number of D-INTs in a SWOTF to only one instance of each Free Spectral Range (FSR) by enabling each D-INT to also integrate the capability to be dynamically re-configured into a cross or a bar state. As with FIG. 13 a polarisation independent structure is depicted in FIGS. 15A and 15B although it would be evident that by omitting the polarisation management components and employing only one WSOS a polarisation dependent design can be implemented.

Now referring to FIGS. 15A and 15B there are depicted exemplary Switchable Wavelength Optical Transmitter Filter (SWOTFs 1500A and 1500B respectively). First exemplary Switchable Wavelength Optical Transmitter Filter, SWOTF 1500A exploits polarization diversity in conjunction with cascades of wavelength selective optical switch (WSOS) elements for each of the polarisations. Pol(1) and Pol(2), coupled to them from an initial polarisation element, such as Polarisation Splitter 1310 in FIG. 13 or a combination of Polarisation Splitter and Polarisation Rotator 210 according to another embodiment of the invention. Second SWOTF 1500B in FIG. 15B depicts the first SWOTF 1500A with additional monitoring ports which exploit the second input of some or all WSOS connected to an additional optical switch and a monitoring photodetector to facilitate circuit calibration, monitoring and configuration.

Now referring to FIG. 15A there is depicted a polarization diverse first SWOTF 1500A exploiting cascades of wavelength selective optical switch (WSOS) elements according to an embodiment of the invention. SWOTF 1500A comprises Polarisation Element 1510B, Upper Circuit 15000A, Lower Circuit 15000B and Wavelength Selective Reflective Filter (WSRF) 1550. Upper Circuit 15000A comprises first Upper WSOS 1520A, second Upper WSOS 1530A and third Upper WSOS 1540A which act upon the upper output U1A of the Polarisation Element 1510B. Lower Circuit 15000A comprises first Lower WSOS 1520B, second Lower WSOS 1530B and third Lower WSOS 1540B which act upon the lower output L1A of the Polarisation Element 1510B. Within other embodiments of the invention WSRF 1550 may be a subsequent optical circuit, optical link, optical component(s), etc. rather than terminating to an electrical output/

Accordingly, each of the Upper Circuit 15000A and Lower Circuit 15000B generates a single wavelength output at the Upper Output UID 1590A and Lower Output L1D 1590B for the polarisation it processes which are then coupled to the WSRF 1550. If the Polarisation Element 1510B is a polarisation splitter then the Upper Circuit 15000A and Lower Circuit 15000B process different polarisations but if the Polarisation Element 1510B is a polarisation splitter with polarisation rotator on one of these polarisations then the Upper Circuit 15000A and Lower Circuit 15000B process the same polarisation. For example, Upper Circuit 15000A would process TE as native TE0 and Lower Circuit 15000B would process TM converted into TE0.

Accordingly, optical signals are coupled to the SWOTF 1500A and initially couple to Polarisation Element 1510 which generates a first output U1A having a first polarisation, e.g. Pol(1), and a second output L1A having a second polarisation, e.g. Pol(2). Within an embodiment of the invention Polarisation Element 1510B is a polarisation splitter, such as Polarisation Splitter 110 in FIG. 1, such that first output U1A has a TE polarisation and second output L1A a TM polarisation or vice-versa. Within another embodiment of the invention Polarisation Element 1510B is a polarisation splitter and rotator, such as Polarisation Splitter and Rotator 210 in FIGS. 2 and 3, such that first output U1A and second output L1A both have a TE polarisation or TM polarisation.

Within the following discussion the description describes Upper Circuit 15000A but it would be evident to one of skill in the art that the Lower Circuit 15000B has a similar structure and functionality with the sole difference being that it is either processing optical signals with a different polarisation when the Polarisation Element 1510 is a polarisation splitter or processing optical signals with the same polarisation when the Polarisation Element 1510 is a polarisation splitter and polarisation rotator.

Within the Upper Circuit 15000A of SWOTF 1500A there are depicted first to third Wavelength Selective Optical Switches (WSOS instances) 1520A, 1530A and 1540A respectively, first and second Points U1B and U1C respectively, and Selected Wavelength Output UID 1590A. SWOTF 1500A by virtue of comprising three stages of WSOS is described below as operating on 8 wavelengths. However, it would be evident to one of skill in the art that the SWOTF 1500A may employ N stages of WSOS, where N is a positive integer, wherein the SWOTF 1500A depicted can uniquely select a single channel from M channels where M is given by Equation (1) below.

$$M = {2}^{N} \qquad ( 1 )$$

Accordingly, as depicted the optical signals at first output U1A are coupled to first Wavelength Selective Optical Switch (WSOS) 1520A which is designed with a first free spectral range, FSR(1) (e.g. FSR(1)=200 GHz), such that considering an incoming stream of optical signals on 100 GHz spacing at wavelengths L(R) where R=1, 2, 3, . . . , 7, 8 then in a first switch state the first WSOS 1520A routes wavelengths L(S) where S=1, 3, 5, 7 . . . to first point U1B. When switched to its second state the first WSOS 1520A routes instead wavelengths L(S) where S=2, 4, 6, 8 first point U1B. Accordingly, the first stage WSOS 1520A may also be referred as an odd-even de-interleaver (D-INT) for Pol(1) whilst WSOS 1520B is a de-interleaver for the same channels for Pol(2) in the context of a polarisation diverse embodiment.

Accordingly, the optical signals propagate forward to second WSOS 1530A from first point U1B. Second WSOS 1530A has been designed with a second free spectral range, FSR(2) where FSR(2)=2*FSR(1). Hence where FSR(1)=200 GHz then FSR(2)=400 GHz. Second WSOS 1530A therefore routes selected wavelengths to second point U1C according to those wavelengths it receives and its switched state.

Table 1 below presents the resulting outputs for second WSOS 1530A for its two switched states given the two switched states the parent WSOS 1520A. Accordingly, in each instance a pair of wavelengths are routed to second point U1C.

TABLE 1
Outputs of Second WSOS 1530A

Second WSOS 1530A

| | | |
|---|---|---|
| First WSOS 1520A | Wavelengths | Wavelengths |

| | Wavelengths at | | at Second | at Fifth Test |
|---|---|---|---|---|
| State | First Point U1B | State | Point U1C | Output 585E |
| A | 1, 3, 5, 7 | A | 1, 5 | 3, 7 |
| | | B | 3, 7 | 1, 5 |
| B | 2, 4, 6, 8 | A | 2, 6 | 4, 8 |
| | | B | 4, 8 | 2, 6 |

Accordingly, the optical signals propagate forward to third WSOS 1540A from second point U1C. Third WSOS 1540A has been designed with a third free spectral range, FSR(3) where FSR(3)=2*FSR(2)=4*FSR(1). Hence where FSR(1)=200 GHz then FSR(3)=800 GHz. Third WSOS 1540A therefore routes a selected wavelength to Switched Wavelength Output (SWOP) UID 1590A, according to those wavelengths it receives and its switch state.

Table 2 below presents the resulting outputs for third WSOS 1540A for its two switch states for each of the different switch state combinations of first WSOS 1520A and third WSOS 1530A. Accordingly, in each instance a single selected wavelength of the 8 initial wavelengths received at input of the SWOTF 1500A are coupled to the SWOP UID 1590A.

TABLE 2
Outputs of SWOP U1D 1590A

| First WSOS 1520A | | Second WSOS 1530A | | Third WSOS 1540A | |
|---|---|---|---|---|---|
| | Wavelengths | | Wavelengths | | Wavelength |
| | at First | | at Second | | at SWOP |
| State | Point U1B | State | Point U1C | State | U1D 1590A |
| A | 1, 3, 5, 7 | A | 1, 5 | A | 1 |
| | | A | | B | 5 |
| | | B | 3, 7 | A | 3 |
| | | B | | B | 7 |
| B | 2, 4, 6, 8 | A | 2, 6 | A | 2 |
| | | | | | 6 |
| | | B | 4, 8 | A | 4 |
| | | | | B | 8 |

The SWOP UID 1590A is coupled to the WSRF 1550 as is the corresponding SWOP L1D of the Lower Circuit 15000B where the corresponding WSOS within Lower Circuit 15000B are driven in the same sequence as those in Upper Circuit 15000A. Accordingly, the WSRF 1550 employs one or more wavelength selective filters such as described above in respect of FIGS. 14A and 14B with Optical Circuit 1480 to provide reflective wavelength filtering for the selected FSR from the Upper Circuit 15000A and Lower Circuit 15000B.

Whilst specific inputs/outputs of the first WSOS 1520A, second WSOS 1530A and third WSOS 1540A are depicted in SWOTF 1500A in FIG. 15A it would be evident that the same input of each subsequent WSOS may be coupled to a different output of the preceding WSOS or that the other input of the subsequent WSOS may be coupled to the different output of the preceding WSOS. Overall, by switching the states of each of the first WSOS 1520A, second WSOS 1530A and third WSOS 1540A a specific wavelength of the 8 input wavelengths is routed to the WSRF 1550. Whilst the specific wavelength at SWOP UID 1590A, and the corresponding L1D 1590B, for each specific state of the first WSOS 1520A, second WSOS 1530A and third WSOS 1540A would be different the different states still allow each of the 8 wavelength ranges to be selected and coupled to the WSRF 1550.

Accordingly, the SWOTF 1500A switches between different wavelength ranges based upon state changes of one or more of the first WSOS 1520A, second WSOS 1530A and third WSOS 1540A and the specific wavelength(s) reflected back to the input port of the SWOTF 1500A are defined by the wavelength filters within the WSRF 1500. As will be evident from WSOS schematic 1500B in FIG. 15A as described below within embodiments of the invention each of the WSOS is controlled via a single control signal and aligned to the grid with a single bias signal.

It would be evident that within an alternate embodiment of the invention that the FSR sequence of the first WSOS 1520A, second WSOS 1530A and third WSOS 1540A may be reversed such that third WSOS 1540A has the smallest FSR, e.g. 800 GHz, 400 GHz, 200 GHz, etc. as appropriate given a 100 GHz channel spacing as an appropriate example. Accordingly, with third WSOS 1540A having FSR(3) then second WSOS 1530A has FSR(2)=2*FSR(3) and first WSOS 1520A has FSR(1)=2*FSR(2)=4*FSR(3). Hence, if FSR(3)=200 GHz then FSR(2) is 400 GHz and FSR(1) is 800 GHz. Whilst this yields a different frequency sequence for the different switch states of first WSOS 1520A, second WSOS 1530A and third WSOS 1540A.

As depicted the Upper Circuit 1500A is controlled via three control signals U1, U2 and U3 respectively whilst Lower Circuit 15000B is controlled via three control signals L1, L2 and L3 respectively.

Now referring to FIG. 15A there is depicted an embodiment of a WSOS, WSOS 1500B, according to an embodiment of the invention exploiting an unbalanced Mach-Zehnder interferometer. As depicted the WSOS 1500B has first and second inputs 15010 and 15020 respectively, a first 3 dB coupler 15030, Switch Element 15040, Bias Element 15050, second 3 dB coupler 15060 and first and second outputs 15070 and 15080 respectively. An optical path imbalance between the first 3 dB coupler 15030 and second 3 dB coupler 15060 is implemented between Switch Element 15040 and Bias Element 15050 which provides the appropriate free spectral range of the WSOS, e.g. FSR(1) for first WSOS 1520A in SWOTF 1500A, FSR(2) for second WSOS 1530A in SWOTF 1500A and FSR(3) for third WSOS 1540A in SWOTF 1500A. Accordingly, each WSOS provides a periodic frequency response. Bias Element 15050 provides for biasing the WSOS to adjust for fabrication variations. Switch Element 15040 provides control of the WSOS such that the frequencies output to first output 15070 and second output 15080 are established for each switch state. Hence, considering WSOS 1500B and first WSOS 1520B then Switch Element 15040 provides for setting the SWOS into either of the two switch states such that in the first switch state the WSOS routes wavelengths L(S) where S=1, 3, 5, 7 . . . to first Output 15070 and wavelengths L (T) where T=2, 4, 6, 8 . . . to second Output 15080. In the second switch state the WSOS routes wavelengths L(S) where S=1, 3, 5, 7 . . . to second Output 15080 and wavelengths L (T) where T=2, 4, 6, 8 . . . to the first Output 15070. Accordingly, each WSOS within the SWOTF is controlled via a single control to the Switch Element 15040 in push, or with two controls to both switch elements 15040 and 15050 in a push-pull mode of operation.

It is noted that in the case 15060 is a 2×2 rather than a 2×1, the cascading of WSOS may allow sharing the output 2×2 15060 of a parent WSOS with the input 2×2 15030 of a child WSOS in a tree of WSOS. It would be evident to one skilled in the art that input couplers 15030 and output couplers 15060 may be both be implemented as a 1×2 Y-branch, 1×2 or 2×2 directional couplers, 1×2 or 2×2 bent directional couplers, 1×2 or 2×2 rapid adiabatic couplers, 1×2 multi-mode interferometers (MMIs) or 2×2 multi-mode interferometers (MMIs).

In the context of WSOS with its embedded optical switching, it is now possible to reduce the SWOTF to a single instances of a cascade of WSOS with a corresponding to a progressive doubling or halving of the free spectral range. Accordingly, with a single tree of cascaded deinterleavers, use of 1×2 for the 15030 input coupler would be sufficient, unless a deliberate use of the second input provided by a 2×2 coupler 15030 would be made for the purpose of circuit calibration, monitoring or configuration, such as described below in respect of SWOTF 1500D in FIG. 15B. The 1×2 or 2×2 MMIs may be angular, such as to output a coupling coefficient which may deliberately not be 50/50, making it possible for the deinterleaving function of a WSOS to have a box-like spectral response by cascading two or more Mach-Zehnder Interferometers (MZIs) with different coupling ratios, within a single instance of a WSOS, whereas it is know in the state of the art that a power coupling coefficient of 29% between a first and the second Mach-Zehnder Interferometer within a WSOS and a power coupling coefficient of 8% in its final output 2×2 would provide a 3^{rd} order Butterworth response. It is also even possible to cascade a third MZI within a WSOS to obtain a 5th order Butterworth response with a power coupling coefficient of 85.2% between the 1st and 2^{nd} MZI, a coupling coefficient of 24.8% between the 2^{nd} and 3^{rd} MZI and a coupling coefficient of 1.5% in the final output 2×2 coupler (or 2×2 MMI).

It would also be possible to introduce additional MZIs within a WSOS with additional thermal tuners, for the purpose of being able to control them separately to ensure the performance of the main MZIs, see for example D. A. B. Miller, “Perfect Optics with Imperfect Components” (Optica 2, 747-750 (2015)) in order to improve the extinction ratio of balanced MZIs and the wavelength extinction ratio of unbalanced MZIs used inside the WSOS. Finally, each WSOS could also be configured with MMIs with even more input and output ports, allowing stacking of WSOS rather than their daisy chain.

It would be evident that whilst an unbalanced MZI is described and depicted with respect to embodiments of the invention that these may be replaced and/or augmented with other optical components. For example, the MZI may be replaced with a Michelson interferometer, a Gires-Tournois interferometer, Fabry-Perot structures, Fibonacci quasi-periodic gratings, ring resonators. Further, the unbalanced MZI or a balanced MZI can be augmented with ring resonators to establish a resonator assisted MZI (RA-MZI). With a RA-MZI more complex filter functions can be generated, such as for example, a 3^{rd} order Butterworth box-like response. Such a RA-MZI may be employed to provide a box-like filter function response to any WSOS stage, without need for cascading MZIs within any WSOS stage, wherein the MZI of the RA-MZI would be further augmented to include an optical switching function, within a SWOTF according to an embodiment of the invention.

Now referring to SWOTF 1500C in FIG. 15B there is depicted an exemplary Switchable Wavelength Optical Transmitter Filter (SWOTF) employing a cascade of wavelength selective optical switches (WSOS) which have their second input port connected to an additional optical switch and monitoring photodetector to provide feedback for circuit calibration, monitoring and configuration. A Polarisation Component 1510 generates signals to U1A with a first polarisation, Pol(1), which are coupled to the Upper Circuit 1500C and other signals to L1A with a second polarisation, Pol(2), which re coupled to the Lower Circuit 15000D.

Within the Upper Circuit 15000C of SWOTF 1500C there are depicted first to third Wavelength Selective Optical Switches (WSOS instances) 1520C, 1530C, and 1540C respectively, first and second Points U1B and U1C respectively, Selected Wavelength Output UID 1590A, first Test Point U2A 1570A, second Test Point U2B 1575A, third Test Point 1580A, first Test Output U3A 1585A, second Test Output U3B 1585B, third Test Output U3C 1585C, fourth Test Output U3D 1585D, fifth Test Output U3E 1585E and sixth Test Output U3F 1585F.

As depicted in SWOTF 1500C in FIG. 15B the first output U1A is coupled to Upper Circuit 15000C whilst second output L1A is coupled to Lower Circuit 15000D. The outputs from the Upper Circuit 15000C and Lower Circuit 15000D being coupled to WSRF 1550 and to Monitor PD 1565 via Optical Switch 1560.

Accordingly, as depicted the optical signals at first output U1A are coupled to first Wavelength Selective Optical Switch (WSOS) 1520 which is designed with a first free spectral range, FSR(1) (e.g. FSR(1)=200 GHz), such that considering an incoming stream of optical signals on 100 GHz spacing at wavelengths L(R) where R=1, 2, 3, . . . , 7, 8 then in a first switch state the first WSOS 1520C routes wavelengths L(S) where S=1, 3, 5, 7 . . . to first point U1B and wavelengths L (T) where T=2, 4, 6, 8 . . . to sixth Test Output U3F 1585F. When switched to its second state the first WSOS 1520C routes instead wavelengths L(S) where S=1, 3, 5, 7 . . . to sixth Test Output U3F 1585F and wavelengths L (T) where T=2, 4, 6, 8 . . . to the sixth Output U1B 1585F.

Accordingly, the optical signals including the channel to be finally selected propagate forward to second WSOS 1530C from first point U1B. Second WSOS 1530C therefore routes selected wavelengths to second point U1C and fifth Test Output 1585E according to those wavelengths it receives and its switch state.

Accordingly, the optical signals including the channel to be finally selected propagate forward to third WSOS 1540C from first point U1B. Third WSOS 1540C therefore routes the selected channel to SWOP UID 1590A and the other remaining optical signal present at the final stage to fourth Test Output 1585D according to those wavelengths it receives and its switch state.

Also depicted within Upper Circuit 15000C is first Test Point U2A 1570A which is coupled to first Test Output U3A 1585A and the other input of first WSOS 1520C. First Test Point U2A 1570A may be an optical switch allowing optical signals coupled to it to be routed to the first Test Output U3A 1585A and the other input of first WSOS 1520C or a passive coupler allowing optical signals coupled to it to be routed to the first Test Output U3A 1585A and the other input of first WSOS 1520C concurrently. First Test Port U2A 1570A therefore allowing for circuit calibration, monitoring and configuration of SWOTF 1500C.

Similarly, within Upper Circuit 15000C is second Test Point U2B 1575A which is coupled to second Test Output U3B 1585B and the other input of second WSOS 1530C. Second Test Point U2B 1575A may be an optical switch allowing optical signals coupled to it to be routed to the second Test Point U3B 1585B and the other input of second WSOS 1530C or a passive coupler allowing optical signals coupled to it to be routed to the second Test Output U3B 1585B and the other input of second WSOS 1530C concurrently. Second Test Point U2B 1575A therefore allowing for circuit calibration, monitoring and configuration of SWOTF 1500C.

Similarly, within Upper Circuit 15000C is third Test Point U2C 1580A which is coupled to third Test Output U3C 1585C and the other input of third WSOS 1540C. Third Test Point U2C 1580A may be an optical switch allowing optical signals coupled to it to be routed to the third Test Point U3C 1575C and the other input of third WSOS 1540C or a passive coupler allowing optical signals coupled to it to be routed to the third Test Output U3C 1585C and the other input of third WSOS 1540C concurrently. Third Test Point U2C 1580A therefore allowing for circuit calibration, monitoring and configuration of SWOTF 1500C.

As depicted SWOTF 1500C also comprises the Lower Circuit 15000D of similar design as the Upper Circuit 15000C but coupled to L1A which receives optical signals with Pol(2) from the Polarisation Component 1510 whilst Upper Circuit 15000C receives optical signals with Pol(2) from the Polarisation Component 1510.

If Polarisation Component 1510 is a polarisation splitter, such as Polarisation Splitter 1310 in FIG. 13, then Pol(1) may be transverse electric (TE) and Pol(2) transverse magnetic (TM) or vice-versa. However, if Polarisation Component 1510 is a polarisation splitter with a polarisation rotator, such as a Polarisation Splitter and Polarisation Rotator combination, then Pol(1) may be transverse electric (TE) or transverse magnetic (TM) and Pol(2) is the same.

The outputs from first Test Output U3A 1585A, second Test Output U3B 1585B, third Test Output U3C 1585C, fourth Test Output U3D 1585D, fifth Test Output U3E 1585E, and sixth Test Output U3F 1585F are depicted as being routed to Optical Switch 1560 as are their corresponding outputs in the Lower Circuit 15000D, namely L1A, L1B, L1C, L1D, L1E and L1F. The Optical Switch 1560 being depicted as having a single output port which is coupled to Monitor PD 1565. Alternatively Optical Switch 1560 may be a pair of optical switches each associated with one of the Upper Circuit 15000C and Lower Circuit 15000D such that these provide the corresponding outputs from each of these to the Monitor PD 1565 or to a pair of Monitor PDs 1565. In this manner, first Test Output U3A 1585A, second Test Output U3B 1585B, third Test Output U3C 1585C, fourth Test Output U3D 1585D, fifth Test Output U3E 1585E, and sixth Test Output U3F 1585F and their corresponding outputs in the Lower Circuit 15000D, namely L1A, L1B, L1C, L1D, L1E and L1F can be used to provide optical feedback for calibration, monitoring and configuration of the SWOTF 1500C such as during an initial die level characterisation prior to packaging, after packaging or as feedback to a control circuit associated with the dynamic selection of wavelength channels during the lifetime operation of SWOTF 1500C.

Optionally, the first Test Point U2A 1570A, second Test Point U2B 1575A and third Test Point 1580A may only couple to their respective WSOS such that the optical paths to and the first Test Output 1585A, second Test Output 1585B and third Test Output 1585C are not implemented. Similarly, the corresponding structures within the Lower Circuit 15000D may be omitted.

Accordingly, it would be evident that optical testing of the SWOTF 1500C can be implemented for the third WSOS 1540C discretely via third Test Point U2C 1580C and fourth Test Output 1585D. Second WSOS 1530C can be discretely optically tested via second Test Point U2B 1575A and fifth Test Output 1585E. First WSOS 1520C can be optically tested discretely via first Test Point U2A 1570A and sixth Test Output 1585F. Optionally, the Optical Switch 1560 and Monitor PD 1565 may be hybridly integrated with the PIC, monolithically integrated within the PIC or external to the PIC. Similarly, WSRF 1550 may be hybridly integrated with the PIC, monolithically integrated within the PIC or external to the PIC.

Accordingly, the WSRF 1550 employs one or more wavelength selective filters such as described above in respect of FIGS. 14A and 14B with Optical Circuit 1480 to provide reflective wavelength filtering for the selected FSR from the Upper Circuit 15000C and Lower Circuit 15000D in FIG. 15B.

Up to this point, the exemplary scenarios described and depicted in FIGS. 15A and 15B, as well as FIG. 13, have been for an 8-channel SWOTF making use of a cascaded sequence of 3 WSOS. However, it would be evident that it would be possible to implement a 16-channel SWOTF with a cascade of four WSOS, a 32-channel SWOTF with a cascade of 5 WSOS, etc. The greater the number of WSOS in the tree, the more complex the control will be and so will the challenge of routing all of the other inputs of the input 2×2 couplers and/or other outputs of the output 2×2 couples of the WSOS to separate monitoring photodetector(s). While it may be possible to route all of them to a single photodetector in the manner described to let the signals integrate into free space onto the facet of the photodetector, it would not be possible to distinguish feedback coming from the 1st stage WSOS versus that of the Nth stage. Here the inventors have pioneered the integration of an additional N×1 optical switch (or multiple instances of smaller radix N×1 optical switches cascaded), allowing to sequentially analyze the optical signals which are not coupled to the output ports of a WSOS stage within a tree of WSOS instances in a SWOTF. The N×1 switch(es) are used to tap the second input of some or each of the WSOS and the optical feedback is used to implement the calibration, monitoring and configuration of the SWOTF.

Control of the WSOS instances in a SWOTF may be effected through monitoring receiver signal strength indicator of a transimpedance amplifier (not illustrated) connected to the high-speed photodetector WSRF 550 while running the calibration, monitoring or control sequences of the SWOTF. Embodiments of the invention support additional monitoring via one (via an N×1 switch) or many PD 560s connected to the other input/output ports of the WSOS instances in a SWOTF.

As depicted the Upper Circuit 5000C is controlled via three control signals U1, U2 and U3 respectively whilst Lower Circuit 5000D is controlled via three control signals L1, L2 and L3 respectively. Each control signal may include one or more sub-controls in the context of push-pull implementation.

Whilst FIG. 13 has described an embodiment of a SWOTF relying on cascade of deinterleavers optimally designed such as to minimize the number of components with the smallest FSR, the WSOS described in FIG. 15A no longer relies on a tree of de-interleavers given the integrated optical switching function within the WSOS and accordingly, it would be evident to one skilled in the art, that the order in which the WSOS are setup could be starting with the largest FSR to end with the smallest FSR, as there is now only one instance of a WSOS for every doubling (or halving) of the FSR at each stage of a cascade of WSOS 15000A and 15000B within a SWOTF 1500A. It would further be evident to one skilled in the art that the order may be from the largest FSR to the smallest FSR in WSOS cascade 15000A while being from the smallest FSR to the largest FSR in WSOS cascade 15000B, yet permitting to select and route the Pol(1) component and the Pol(2) component of the same channel to WSRF 1550.

Within another embodiment of the invention it would also be possible to set-up the cascade of WSOS within Upper Circuit 15000A and Lower Circuit 15000B within the 8-channel SWOTF 1500A as depicted in FIG. 15A according to a different sequence of WSOS elements. Considering a channel spacing of 100 GHz, then it is necessary to have at least one WSOS with an FSR of 200 GHz, at least one another WOSO with an FSR of 400 GHz and at least one further WSOS with an FSR of 800 GHz. However, the WSOS do not need to be in the order 200 GHz, 400 GHz and 800 GHz as described elsewhere within this specification or the reverse sequence of 800 GHz, 400 GHz, and 200 GHz. Rather, it is merely a requirement for them all to be employed. Accordingly, different orders can be employed without any need for WSOS to be into any sequential order.

Accordingly, it would be possible to generalize the SWOTF to select among N channels to have;
i) Log 2(N) number of WSOS stages in either a single cascade (polarisation independent WSOS stages) or within each cascade (polarisation dependent WSOSO stages, wherein, the first WSOS stage, has an FSR that is twice that of the channel spacing, and;
ii) Log 2(N))−1 other WSOS stages following a series I=2, 3, 4, 5, 6, 7, 8, 9, etc, with a distinct FSR corresponding to the channel spacing multiplied by 2\hat{ }I, and;
iii) with no need for the WSOS stages to be into any prescribed sequential order within the cascade or cascades.

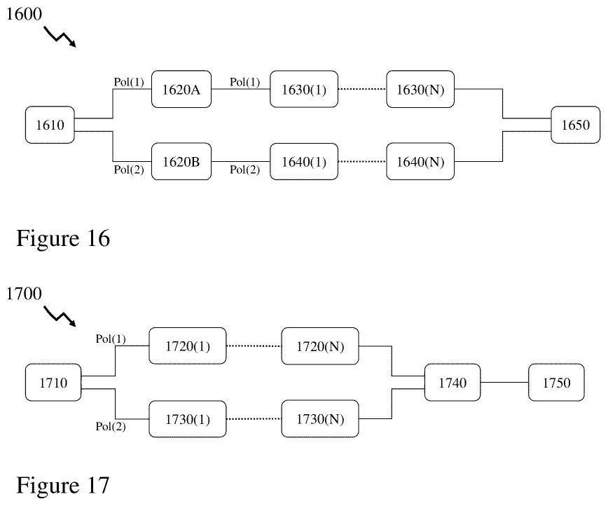

FIG. 16 depicts a polarisation diverse Switchable Wavelength Optical Transmitter Filter (SWOTF) 1600 exploiting WSOS based Mach-Zehnder deinterleavers with integrated optical switching according to an embodiment of the invention. As depicted the SWOTF 1600 comprises a Polarisation Element 1610 generating an upper stream with a first polarisation Pol(1) and a lower stream with second polarisation Pol(2). The upper stream is then passed by second Polarisation Element 1620A whilst the lower stream is passed by third Polarisation Element 1620B. The upper Pol(1) stream is processed by first to N upper WSOS instances 1630(1) to 1630(N) respectively before being coupled to PD 1650 whilst the lower Pol(2) stream is processed by first to N lower WSOS instances 1640(1) to 1640(N) respectively before being coupled to PD 1650. As discussed above first Polarisation Element 1610 may generate Pol(1)≠Pol(2) or it may generate Pol(1)=Pol(2). In either instance the second and third Polarisation Elements 1620A and 1620B are designed to improve the polarisation extinction ratio in their respective streams. Within an embodiment of the invention each WSOS of the first to N upper WSOS instances 1630(1) to 1630(N) respectively and first to N lower WSOS instances 1640(1) to 1640(N) respectively may be a cascade of Mach-Zehnder deinterleavers element combined with an optical switch such as described and depicted in respect of FIGS. 15A and 15B respectively. Polarisation Element 1620A may be either a polarisation splitter or a polarisation splitter rotator.

However, in either the cascade of Mach-Zehnder deinterleavers and/or a PIC switch polarisation crosstalk can be induced due to random variations in the widths of the optical waveguides due to manufacturing imperfections. Accordingly, within each WSOS, where additional polarisation crosstalk may be induced, a wavelength dependent crosstalk may result due to PIC implementations where the refractive indices and phase shifts of the TE and TM polarisations are different, each WSOS instances will exhibit a different FSR for the TE and TM polarisations, together with red/blue shifts from desired design point. Accordingly, unless additional polarisation filtering is added at the entrance or exit of a cascade of WSOS for a given polarization, then increased wavelength dependent crosstalk will be observed from the polarisation crosstalk.

Now referring to FIG. 17 there is depicted a polarisation diverse SWOTF 1700 exploiting WSOS based Mach-Zehnder deinterleavers with integrated optical switching according to an embodiment of the invention. As depicted the SWOTF 1700 comprises a Polarisation Element 1710 generating an upper stream with a first polarisation Pol(1) and a lower stream with second polarisation Pol(2). The upper Pol(1) stream is processed by first to N upper WSOS instances 1720(1) to 1720(N) respectively before being coupled to Polarisation Combiner 1740 and therein to PD 1750 whilst the lower Pol(2) stream is processed by first to N lower WSOS instances 1730(1) to 1730(N) respectively before being coupled to Polarisation Combiner 1740 and therein to PD 1750. As discussed above first Polarisation Element 1710 may generate Pol(1)≠Pol(2) or it may generate Pol(1)=Pol(2). The Polarisation Combiner provides a means of reducing the polarization dependent inter-channel crosstalk arising within the multiple WSOS instances from the non-perfect vertical sidewalls of the channel waveguides within the PIC comprising the WSOS instances. The use of the polarisation combiner 1740 also makes it possible to reduce the number of waveguides facing the PD 1750 down to a single waveguide, which helps improving coupling efficiency to the PD 1750 as well as simplifies the coupling to PD 1750. Polarisation Elements 1710 and 1740 may be either matched polarisation splitters & polarisation combiners or matched polarisation splitter rotators & polarisation rotator combiners.

Whilst within the following embodiments of the invention structures are described as being formed within the substrate for the insertion of other optical elements and/or the insertion of materials which are subsequently processed to form an optical interconnection through etching based upon the embodiments of the invention being described with respect to silicon as a substrate it would be evident that within other embodiments of the invention according to the substrate that other manufacturing processes may be employed to form the structures either through the selective removal of material, e.g. through ablation for example, through the selective addition of material, e.g. deposition, sintering, fusing, etc., through the initial shaping of the material, e.g. through stamping or fabrication by deposition onto a template etc. or a combination thereof.

Within embodiments of the invention an optical waveguide and/or optical element may be formed or partially formed using doping to selectively increase or decrease the refractive index of the material in dependence upon the dopant employed and its concentration within the material doped. Within semiconductors such dopants are typically other semiconductor materials however a dopant may be any element or combination of elements achieving the desired result such as hydrogen, deuterium, erbium, and ytterbium for example. In some embodiments multiple doping profiles may be employed to create the desired final refractive index profile. In some embodiments of the invention this doping may trigger the formation of vacancies within the lattice of the material or substitute an element into the lattice of the material.

Within embodiments of the invention an optical waveguide and/or optical element may be formed or partially formed using the induction of damage to selectively increase or decrease the refractive index of the material in the damaged region in dependence upon the degree of damage induced. In some embodiments multiple damage profiles may be employed to create the desired final refractive index profile. In embodiments of the invention an aspect of the induction of damage may be employed to tune the location of the induced damage such that, for example, damage reducing a refractive index is induced at a predetermined depth below the surface of the material being damaged. Such damage may be induced from atomic bombardment, e.g. proton bombardment, electron bombardment, ion bombardment, infrared (IR) radiation, visible radiation, ultraviolet (UV) radiation, microwave radiation, radio frequency (RF) radiation, X-ray radiation, electron beam radiation, ion beam radiation, an ultrasonic signal, an acoustic signal and a hypersonic signal. In some embodiments of the invention this induced damage may be the formation of vacancies within the lattice of the material.

Within the following description, photonic wire bonds are described and presented as being formed through, for example, two-photon absorption triggered processes within a liquid photosensitive materials to generate the waveguide core and waveguide cladding(s) of the PWB wherein through controlled positioning and movement of the incident beam(s) of light, three-dimensional (3D) optical waveguides (waveguides) which are self-supporting can be generated. The inventors refer to these waveguides as being free-form waveguides as the geometry and/or position of the waveguide can be defined based upon factors including computer aided design (CAD), optical simulations, and the physical positions of the optical elements to which the PWB interfaces at either end.

Accordingly, the PWBs can support mode field diameter (MFD) conversion and matching position along these PWBs (interconnection links) between independent optical circuits components such as singlemode or multimode optical waveguides (e.g. optical fiber waveguides referred to as optical fibers within this specification) and/or planar integrated waveguides of different material systems and designs, referred to as integrated optical waveguides or simply waveguides within this specification such as two-dimensional (2D) or planar waveguides and 3D or channel waveguides as referred to in the art.

Subsequent to placement of the two optical elements to be connected with the PWB a PWB manufacturing system employing automated moving stages and/or positioning arms in combination with image processing and pattern recognition algorithms locates the waveguide cores, for example, of the optical elements being interconnected and then locally prints the photonic wire bonds, referred as they function as an optical/photonic equivalent between waveguide cores to be interconnected as do electrical wirebonds between electrical structures to be interconnected. This process provides low-cost, low-loss optical interconnections within production-friendly embodiments that are scalable for mass-volume production.

Importantly, the integration of a photonic wire bond between waveguides provides for a defined and repeatable alignment between the waveguides such that the PWB can “absorb” mismatches arising from manufacturing tolerances which would otherwise either lead to high insertion losses or increased costs of manufacturing to achieve tighter manufacturing tolerances.

However, it would be evident to one of skill in the art that other direct write or additive manufacturing technique may be employed to generate the PWB(s) without departing from the scope of the invention. Further, whilst the light-based methodologies described and depicted exploit what the inventors refer to later in this specification as a “pool” of the light sensitive material(s) to form the waveguide core/cladding it would be evident that within other embodiments of the invention alternate deployment means for a selectively curing a material may be employed such as other optical or non-electrical techniques. “Curing” may for example be through cross-linking, optically induced polymerization, electron bombardment polymerization, thermal polymerization, ultrasonically triggered polymerization etc. Optionally, two or more beams may be employed to “write” the PWB wherein each beam is at an intensity insufficient to trigger the transition in the material from liquid to solid but the overlapping point of these beams has sufficient intensity to trigger the transition. Optionally, a single beam may be employed with a very shallow focal depth such that in the unfocussed regions the power density is insufficient to trigger the transition in the material from liquid to solid but the focal point has sufficient power density to trigger the transition.

Optionally, it would be evident that other direct write techniques such as additive manufacturing techniques may be employed without a “pool” of material. For example, WO/2018/145,194 entitled “Methods and Systems for Additive Manufacturing” describes techniques referred to as Selective Spatial Solidification to form a 3D piece-part directly within a selected build material whilst Selective Spatial Trapping “injects” the build material into a manufacturing system and selectively directs it to accretion points in a continuous manner.

Within the following sections exemplary PWB interconnections are described with respect to the interconnection of optical elements/optical waveguides. It would be evident to one of skill in the art that the PWB interconnection designs and methodologies as described may be applied to other optical interconnections either discretely or in combination without departing from the scope of the invention.

Within this section the specific context of writing a photonic wire bonding link between an optical fiber and an integrated photonics silicon nitride waveguide is described and presented in order to present the techniques for forming a photonic wire bond. However, it would be evident that in order to provide a fixed and repeatable alignment between a first optical waveguide (e.g. an optical fiber in a first instance or silicon nitride waveguide in a second instance) and a second optical waveguide (e.g. a silicon nitride waveguide in the first instance and a semiconductor waveguide in the second instance) allowing the implementation of automated photonic wire bonding writing recipes essential to mass-production schemes requires that the first optical waveguide and second optical waveguide be positioned/retained in a similarly automated/mass production manner.

However, it would be evident to one of skill in the art that the optical fiber represents an example of an optical element which is coupled to an optical waveguide upon a substrate. In fact within some embodiments of the invention the optical element may be a short section of an optical fiber such as a graded index fiber, where the “core” has a refractive index that decreases with increasing radial distance from the optical axis of the fiber, a photonic crystal fiber (PCF), a photonic-bandgap fiber PCF which confines photonic signals by band gap effects, a holey fiber PCF using air holes in their cross-sections, a hole-assisted fiber PCF which guides photonic signals by a conventional higher-index core modified by the presence of air holes, and a Bragg fiber which is photonic-bandgap fiber formed by concentric rings of material.

For example, in the instance of an optical fiber the inventors have worked to develop custom U-groove structures formed within 200 mm (8″) diameter silicon-on-insulator (SOI) wafers where the thickness of the top silicon slab is engineered to make the optical fiber cores co-planar and co-axial with the silicon nitride waveguide cores to which they to be coupled thereby improving the positional alignment and reducing the misalignment that the photonic wire bond (PWB) is required to absorb. Descriptions with respect to such structures are described and depicted within WO/2020/093136 entitled “Structures and Methods for Stress and Gap Mitigation in Integrated Optical Microelectromechanical Systems” for example.

Accordingly, within embodiments of the invention U-grooves are etched into a top silicon slab using any suitable anisotropic patterning process(es), such as Deep Reactive Ion Etching (DRIE) for instance, with a Buried Oxide (BOX) layer acting as an etch-stop to provide a repeatable etch depth. These U-grooves have their lengths, widths and depths engineered to tightly receive and host the stripped ends of optical fibers (e.g. 125 μm outer diameter singlemode optical fibers such as Corning SMF-28 for example), position them to within a specified tolerance (e.g. ±1 um in vertical and lateral directions) from the axis of the silicon nitride waveguides whilst providing sufficient space for the controlled dispense and capillary-force driven infiltration of structural (and/or optical) UV (and/or thermally) curable adhesives to fix the optical fibers within the U-grooves. A controlled dispense is engineered to provide for both thermo-mechanical stability of the fiber in the U-Groove and an optimal index contrast to enhance the fiber core detection by the vision system of the photonic wire bonding writing tool. The U-Grooves lengths are also engineered to set a repeatable distance in the horizontal direction between the end facet of the optical fiber and the opposing silicon nitride waveguide.

However, the optical fibers may be fixed into position with other mechanisms such as metallized fiber/solder to metallization on the silicon substrate or optical waveguide stack, attachment of a top-cover over the U-grooves and optical fibers etc. Further, the dimensions of exemplary embodiments of the invention are provided with respect to those specific embodiments of the invention and may be varied within the same embodiments of the invention or other embodiments of the invention without departing from the scope of the invention.

Within embodiments of the invention as depicted and described below the interface region between the U-groove structure(s) and the optical waveguide(s) comprises a customized receptacles (referred to as a pool by the inventors) such that this pool can be filled with one or more materials from which the PWB is formed is located between the optical fibers and the silicon nitride waveguides. These pools receive and contain, for example, a liquid photoresist from which the photonic wire bonding core is written with a UV direct write process. The dimensions of the pools provide for line-of-sight visual access of the PWB manufacturing system to the cores of the optical fiber and silicon nitride waveguide so that the vision system of the PWB writing tool can locate them and lock onto them. The dimensions of the pools provide for repeatable, sufficient, yet minimal volume of the photoresist to be dispensed and maintained in location to ensure a repeatable PWB writing process.

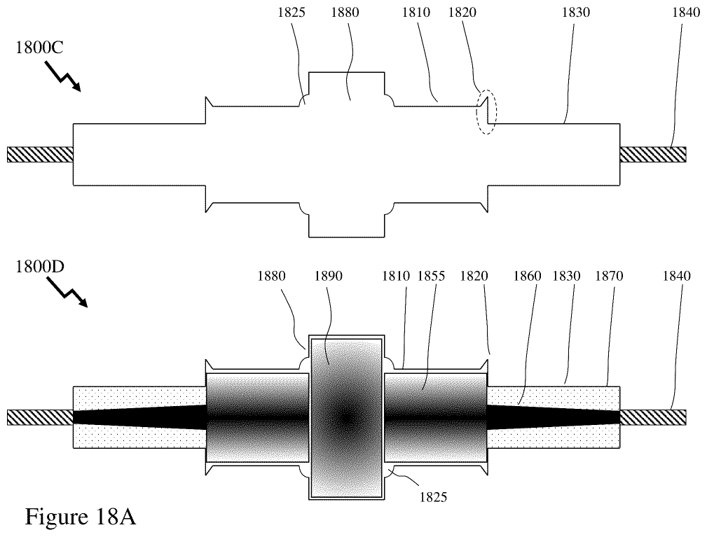

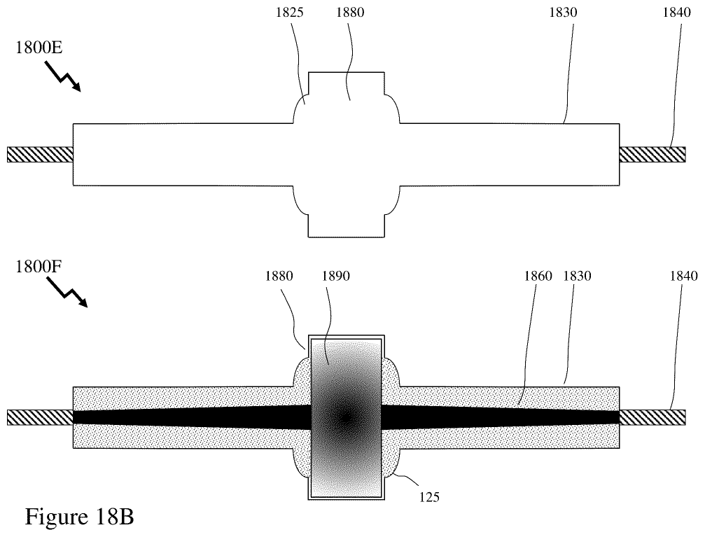

Referring to FIG. 18A there are depicted first and second Views 1800C and 1800D of a mechanical structure for the formation of a PWB 1860 between a graded index optical fiber (GRIOF) 1855 within a U- or V-groove 1810 formed within a silicon substrate and an Optical Waveguide 1840 formed upon the silicon substrate according to an embodiment of the invention wherein the GRIOF 1855 is coupled to another Optical Element 1890 which may be passive or active according to the specific requirements of the overall optical circuit the mechanical structure forms part of. As depicted in first and second Views 1800C and 1800D a pair of U- or V-grooves 1810 are formed either side of an Opening 1880 within which the Optical Element 1890 is disposed. Accordingly, an optical signal at the left hand side of the structure depicted in first and second Views 1800C and 1800D is initially guided within a first Optical Waveguide 1840 before being coupled to a first GRIOF 1855 via a first PWB 1860 wherein it is coupled to the Optical Element 1890. From the Optical Element 1890 the optical signals processed by the Optical Element 1890 are coupled to a second GRIOF 1855 and therein via a second PWB 1860 to a second Optical Waveguide 1840.

Within an embodiment of the invention the GRIOF 1855 acts as a graded index (GRIN) lens whilst within other embodiments it is replaced with a GRIN lens. Within embodiments of the invention the GRIOF 1855 or GRIN lens may be circularly symmetric in refractive index profile whilst within other embodiments of the invention it may be circularly asymmetric.

In contrast, as depicted in FIG. 18B in first and second Views 1800E and 1800F the PWBs 1860 may be able to accommodate the required optical mode geometry adjustments then the Optical Waveguides 1840 are coupled to the Optical Element 1890 via the PWBs 1860 directly. The PWB may implement a circularly symmetric mode transformation along its length or it may implement a non-circularly symmetric mode transformation.

Optionally, the PWB 1860 may be implemented in two or more steps using different material combinations for the different sections.

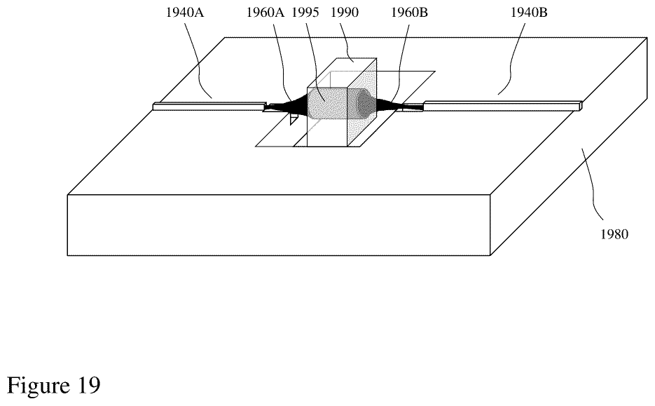

Referring to FIG. 19 there is depicted a perspective schematic of an interconnection between an input waveguide 1940A and an output waveguide 1940B via an Optical Element 1990 wherein the interconnection between the input waveguide 1940A and Optical Element 1990 is via a first PWB 1960A and the interconnection between the output waveguide 1940B and the Optical Element 1990 is via a second PWB 1960B. The Optical Element 1990 comprising an Optical Structure 1995 within where the Optical Element 1990 is depicted within an opening within the Substrate 1980, such as Opening 1880 depicted in FIG. 18B.

Within exemplary embodiments of the invention the optical waveguides, e.g., Optical Waveguide 1940 in FIG. 19, employed for the PICs and therein coupling to and/or from other optical elements with PWBs are based upon a 450 nm thick Silicon Nitride (SixNy, referred to subsequently as SiN for ease of reference) core symmetrically clad with 3.2 μm of Silicon Oxide (SiO2) above and below. This material choice provides an advantage over waveguides with silicon cores in regard to PWBs because the lower core-clad refractive index contrast results in larger mode field diameters (MFD) than silicon waveguides. Larger MFDs allow for more overlap in the interconnection region, which results in increased tolerances with respect to misalignment between the PWB and the SiN cores to achieve low-loss optical links.

Within embodiments of the invention the SiN waveguide cores are patterned with tapers in the region close to the interface with the PWB core in order to increase the MFD further, thereby providing an additional relaxation of the core-to-core alignment constraints and tolerances. The relatively larger PWB cores provide improved scalability of the technology towards shorter wavelengths, making the technology applicable to PIC devices operating in different wavelength ranges including the L, C, S, E and O-bands of the infrared telecommunications spectrum, namely 1565 nm-1625 nm, 1530-1565 nm, 1460-1530 nm, 1360-1460n and 1260 nm-1360 nm respectively.

Within embodiments of the invention the SiN waveguide cores are patterned with square cross-section tapers in the region closest to the interface with the PWB core in order to provide mode fields with angular symmetry such that when coupled with photonic wire bonding cores with cylindrical symmetry, optical interfaces with low polarization sensitivity are produced.

Within FIGS. 18A, 18B and 19 optical element, Optical Element 1890 or 1990, is depicted as being mounted directly upon the same substrate as that of the optical waveguides, e.g. Optical Waveguide 1840, and within which Pools 1830, U-Grooves 180 and the Opening 1880 are formed. However, within other embodiments of the invention the Optical Element 1890, whether providing a passive function, active function or a combination thereof, the Optical Element 1890 may be formed upon an intermediate support die (ISD). The ISD may provide appropriate characteristics such as thermal expansion coefficient, relative to that provided by the substrate.

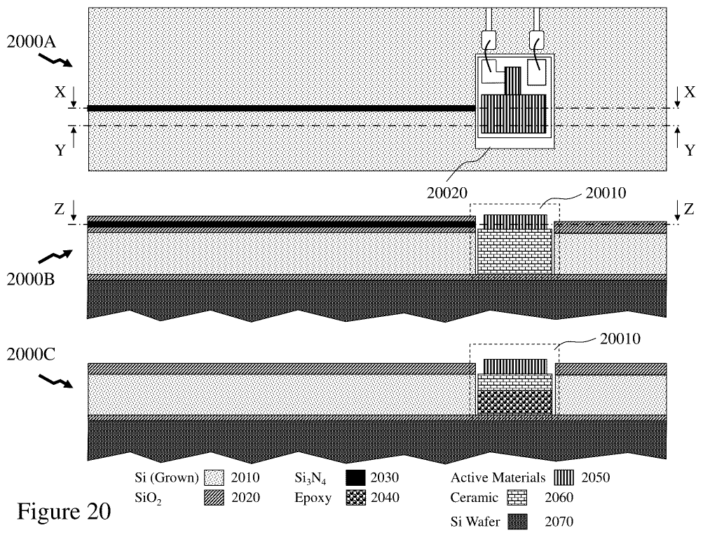

Now referring to FIG. 20 there is depicted schematically the integration of an ISD die with a thin film active element such as a semiconductor optical amplifier SOA discretely or as part of an integrated photonics silicon chip (IPSC) according to an embodiment of the invention. Accordingly, the ISD 5010 employs a design concept as depicted in first to third Images 400A to 400C respectively with a Thin Film Active Element (e.g. one or more SOA(s), an SOA with multiple parallel elements, or an IPSC with integral SOA(s)) which is not identified within FIG. 20.

Accordingly, within FIG. 20 there is depicted Plan 2000A together with first and second Cross-Sections 2000B and 2000C respectively along Sections X-X and Y-Y, respectively. Plan 2000A being along Section Z-Z within first Cross-Section 2000B. Accordingly, the ISD 20010 is depicted inserted into a Cavity 20020 formed within the device stack formed atop the BOX (SiO2 2020) formed upon the Si Wafer 2070. Accordingly, the Cavity 20020 is etched into the Si (Grown) 2010, SiO2 2020, and Si3N4 2030 grown atop the BOX. The ISD 20010 is attached via Epoxy 2040 within the recess in the lower surface of the ISD Carrier formed from Ceramic 2060 upon which are formed the electrical contacts (e.g. Anode and Cathode Pads) together with the Thin Film Active Element formed from the Active Material(s) 2050.

Within other embodiments of the invention according to the design of the ISD Carrier and the structure grown on the Si Wafer 2070 the cavity may be formed by etching to a shallower depth than the BOX or alternatively within other embodiments of the invention the cavity may be formed by etching to a deeper depth than the BOX such that cavity also extends down into the Si (Grown 510).

An assembly process for the IPSC and ISD employs the ISDs being inserted into the cavities within the upper surface of the IPSC. This may be with pick-and-place tools that can be active or passive and is engineered to optimize the optical to the waveguide facets. The attachment of the ISDs is made using an epoxy which may be conductive, non-conductive, ultraviolet (UV) curable, thermally curable etc. Other attachment techniques may be employed but with increased complexity. The design of the ISD Carrier is such that its thickness aligns the active element, e.g. Thin Film Active Element with the optical waveguide(s) it is intended to be coupled to/from.

As depicted in FIGS. 20 the ISD 20010 is coupled to a single optical waveguide although it would be evident that an input and/or an output side may both contain a single optical waveguide and/or multiple optical waveguides disposed across the substrate. As depicted in FIG. 20 the ISD 5010 is coupled to a single optical waveguide vertically although it would be evident that the input and/or the output side may contain multiple optical waveguide layers disposed vertically with respect to the substrate in other embodiments of the invention.

Within FIG. 20 the ISD is depicted as directly coupled to the optical waveguide(s). Further, only a waveguide on one side of the ISD is depicted although it would be evident to one of skill in the art that optionally other waveguides may be disposed on another other side of the ISD such that optical waveguides are coupled to the Thin Film Active Element from multiple directions and/or from one or more waveguides to another waveguide or waveguides via Thin Film Active Element.

However, within other embodiments of the invention such as described and depicted in FIG. 19 may interface to the IPSC via one or more PWBs.

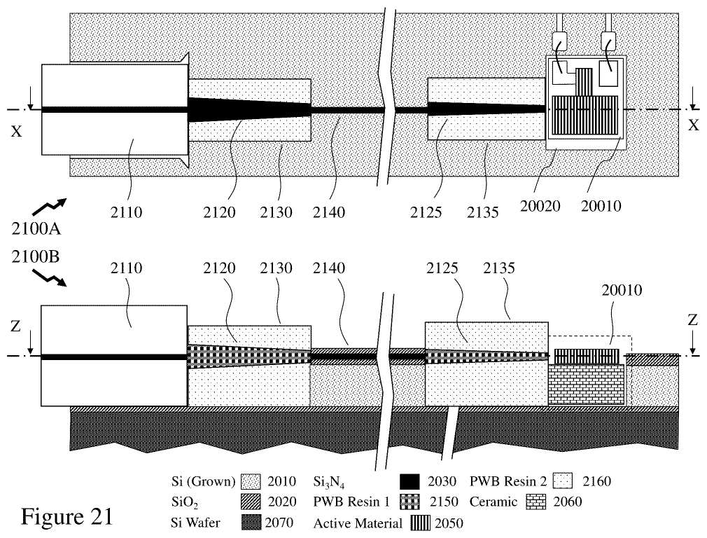

Referring to FIG. 21 there is depicted a schematic of an IPSC showing the optical fiber and ISD sections according to an embodiment of the invention with a thin film active ISD die and dual PWB sections.

Accordingly, referring to FIG. 21 there is depicted a Plan 2100A along section Z-Z and Cross-Section 2100B along section X-X of an IPSC showing the optical fiber, PWB and ISD sections. Accordingly, the ISD 20010 is depicted as it was in FIG. 20 on the right-hand side. On the left-hand side is the Optical Fiber 2110 disposed within the U-Groove, not identified for clarity, wherein a first PWB has been formed between the Optical Fiber 2110 and Optical Waveguide 2140 comprising a first PWB Core 2120 formed from PWB Resin 1 2150 and a first PWB Cladding 2130 formed from PWB Resin 2 2160. Optionally, the first PWB may be formed solely from PWB Resin 1 2150 if it is air clad or from multiple core materials and/or multiple cladding materials.

Also depicted is a second PWB which has been formed between the Optical Waveguide 2140 and ISD 20010 comprising a second PWB Core 2125 formed from PWB Resin 1 2150 and a second PWB Cladding 2135 formed from PWB Resin 2 2160. Optionally, the second PWB may be formed solely from PWB Resin 1 2150 if it is air clad or from multiple core materials and/or multiple cladding materials. Within other embodiments of the invention the core and/or cladding materials of the first PWB may be different to those employed for the second PWB based upon the requirements of the Optical Fiber 2110, Waveguide 2140 and ISD 20010.

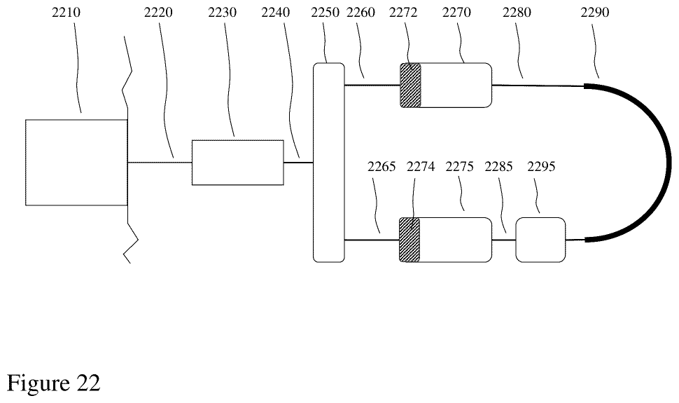

Now referring to FIG. 22 there is depicted a schematic of an IPSC for a hybrid integrated external cavity laser with a pair of gain blocks according to an embodiment of the invention. As depicted an Optical Fiber 2210 is coupled to an Output Waveguide 2220 of the ECL. The distal end of the Output Waveguide 2220 being coupled to a Waveguide Isolator 2230, for example an isolator such as described in respect of FIGS. 18A-19 or another micro-isolator inserted into a cavity. The Waveguide Isolator 2230 being coupled to an output port of a Power Combiner 2250 via a first PWB 2240. One input port of the Power Combiner 2250 is coupled via a second PWB 2260 to a first Optical Gain Element 2270 whilst the other input port of the Power Combiner 2250 is coupled via a third PWB 2265 to a second Optical Gain Element 2275. The first Optical Gain Element 2270 is also coupled to a fourth PWB 2280 and therein to one end of a Bragg Grating 2290. The second Optical Gain Element 22275 is coupled to another end of the Bragg Grating 2290 via fifth PWB 2285, Phase Shifter 2295. The facet of the first Optical Gain Element 2270 disposed towards the Power Combiner 2250 has a high reflectivity (HR) Coating 2272 to provide a high reflectivity reflector. Similarly, the facet of the second Optical Gain Element 2275 disposed towards the Power Combiner 2250 has another HR Coating 2274 to provide a high reflectivity reflector.

Within an embodiment of the invention with a transmissive Bragg Grating 2290 the ECL is thereby formed between the another HR Coating 2274 of the second Optical Gain Element 2275 and the HR Coating 2272 of the first Optical Gain Element 2270 wherein the emitting wavelength of the ECL is defined by the Bragg Grating 2290.

Within another embodiment of the invention with a reflective Bragg Grating 2290 then ECL is formed by a first element between the another HR Coating 2274 of the second Optical Gain Element 2275 and the Bragg Grating 2290 and a second element between the HR Coating 2272 of the first Optical Gain Element 2270 and the Bragg Grating 2290. Accordingly, the emitting wavelength of the first element and second element of the ECL are defined by the Bragg Grating 2290.

Within another embodiment of the invention one path to the Power Combiner 2250 may incorporate a polarisation rotator and the Power Combiner 2250 is replaced with a polarisation combiner as the two paths are now of orthogonal polarisations.

Within another embodiment of the invention the Power Combiner 2250 may be replaced with a 1×N device rather than the 1×2 depicted where N is an even integer greater than of equal to 2. In this embodiments pairs of ports from the 1×N device each couple to an ECL structure similar to that depicted to the right hand side of Power Combiner 2250 in FIG. 22 such that a plurality of ECLs each at wavelengths defined by their respective Bragg Gratings are nested reducing the footprint of the multi-wavelength ECL. Optionally, the passive 1×N device may be replaced with a 1×2 splitter and 2 1×M, where M=N/2, switches such that the ECL can be selectively switched. Other variants with other splitter/switch combinations being possible to select 2, 3 or more wavelengths to the output port of the ECL.

Optionally, within other embodiments of the invention the Bragg Grating 2290 may be replaced with a tunable optical filter to provide a tunable ECL structure. This structure being similarly nestable as described above.

Specific details are given in the above description to provide a thorough understanding of the embodiments. However, it is understood that the embodiments may be practiced without these specific details. For example, circuits may be shown in block diagrams in order not to obscure the embodiments in unnecessary detail. In other instances, well-known circuits, processes, algorithms, structures, and techniques may be shown without unnecessary detail in order to avoid obscuring the embodiments.

The foregoing disclosure of the exemplary embodiments of the present invention has been presented for purposes of illustration and description. It is not intended to be exhaustive or to limit the invention to the precise forms disclosed. Many variations and modifications of the embodiments described herein will be apparent to one of ordinary skill in the art in light of the above disclosure. The scope of the invention is to be defined only by the claims appended hereto, and by their equivalents.

Further, in describing representative embodiments of the present invention, the specification may have presented the method and/or process of the present invention as a particular sequence of steps. However, to the extent that the method or process does not rely on the particular order of steps set forth herein, the method or process should not be limited to the particular sequence of steps described. As one of ordinary skill in the art would appreciate, other sequences of steps may be possible. Therefore, the particular order of the steps set forth in the specification should not be construed as limitations on the claims. In addition, the claims directed to the method and/or process of the present invention should not be limited to the performance of their steps in the order written, and one skilled in the art can readily appreciate that the sequences may be varied and still remain within the spirit and scope of the present invention.

What is claimed is:

1. An optical emitter comprising:
a wavelength specific optical portion for defining one or more wavelengths of an optical signal emitted by the optical emitter; and
an optical gain portion for generating the optical signal.

2. The optical emitter according to claim 1, wherein
the wavelength specific optical portion comprises:
a wavelength dependent reflective filter settable to a predetermined centre wavelength within a defined wavelength range and a predetermined passband; and
an optical splitter having an input port and a plurality of output ports wherein the input port is optically coupled to the wavelength dependent reflective filter; and
the optical gain portion comprises:
a plurality of optical gain elements each having an input port and an output port; wherein
the input port of each optical gain element of the plurality of optical gain elements is coupled to a predetermined output port of the plurality of output ports of the optical splitter;
each output port of each optical gain element of the plurality of optical gain elements is optically coupled to a high reflectivity facet; and
the optical emitter generates a plurality of optical outputs from each high reflectivity facet of the plurality of optical gain elements with an optical emission spectrum defined by the wavelength dependent reflective filter.

3. The optical emitter according to claim 1, wherein
the wavelength specific optical portion comprises:
a wavelength dependent reflective filter settable to a predetermined centre wavelength within a defined wavelength range and a predetermined passband; and
an optical switch comprising an input port and a plurality of output ports wherein the input port is optically coupled to the wavelength dependent reflective filter and optical signals at the input port are switchably coupled to one output port of the plurality of output ports; and
the optical gain portion comprises:
a plurality of optical gain elements each having an input port and an output port; wherein
the input port of each optical gain element of the plurality of optical gain elements is coupled to a predetermined output port of the plurality of output ports of the optical switch;
each output port of each optical gain element of the plurality of optical gain elements is optically coupled to a high reflectivity facet; and
the optical emitter generates a plurality of optical outputs from each high reflectivity facet of the plurality of optical gain elements with an optical emission spectrum defined by the wavelength dependent reflective filter.

4. The optical emitter according to claim 1, wherein
the wavelength specific optical portion comprises:
a plurality of wavelength dependent reflective filters where each wavelength dependent reflective filter having a predetermined centre wavelength and a predetermined passband;
an optical splitter having a plurality of input ports and a plurality of output ports wherein each input port is optically coupled to a predetermined wavelength dependent reflective filter of the plurality of wavelength dependent reflective filters; and
the optical gain portion comprises:
a plurality of optical gain elements each having an input port and an output port; wherein
the input port of each optical gain element of the plurality of optical gain elements is coupled to a predetermined output port of the plurality of output ports of the optical splitter;
each output port of each optical gain element of the plurality of optical gain elements is optically coupled to a high reflectivity facet; and
the optical emitter generates a plurality of optical outputs from each high reflectivity facet of the plurality of optical gain elements with an optical emission spectrum defined by the plurality of wavelength dependent reflective filters.

5. The optical emitter according to claim 1, wherein
the wavelength specific optical portion comprises:
a plurality R wavelength dependent reflective filters where each wavelength dependent reflective filter having a predetermined centre wavelength and a predetermined passband;
an optical splitter having a plurality N input ports and a plurality M output ports; and
a plurality N-R reflectors;
the optical gain portion comprises:
a plurality M optical gain elements each having an input port and an output port; wherein
the input port of each optical gain element of the plurality M optical gain elements is coupled to a predetermined output port of the plurality M output ports of the optical splitter;
each output port of each optical gain element of the plurality of optical gain elements is optically coupled to a high reflectivity facet;
R inputs ports of the optical splitter are optically coupled to a predetermined wavelength dependent reflective filter of the plurality R wavelength dependent reflective filters;
N-R inputs ports of the optical splitter are optically coupled to a reflector of the plurality N-R reflectors;
the optical emitter generates a plurality of optical outputs from each high reflectivity facet of the plurality of optical gain elements with an optical emission spectrum defined by the plurality R wavelength dependent reflective filters;
R is an integer greater than or equal to 1;
N is an integer greater than or equal to 2; and
M is an integer greater than or equal to 1.

6. The optical emitter according to claim 1, wherein
the wavelength specific optical portion comprises:
a plurality R wavelength dependent reflective filters where each wavelength dependent reflective filter having a predetermined centre wavelength and a predetermined passband;
an optical splitter having a plurality T input ports and a plurality M output ports;
an optical switch having N input ports and T output ports; and
a plurality N-R reflectors;
the optical gain portion comprises:
a plurality M optical gain elements each having an input port and an output port; wherein
the input port of each optical gain element of the plurality M optical gain elements is coupled to a predetermined output port of the plurality M output ports of the optical splitter;
each output port of each optical gain element of the plurality of optical gain elements is optically coupled to a high reflectivity facet;
R inputs ports of the optical switch are optically coupled to a predetermined wavelength dependent reflective filter of the plurality R wavelength dependent reflective filters;
N-R inputs ports of the optical switch are optically coupled to a reflector of the plurality N-R reflectors;
each of the output ports of the optical switch is coupled to an input port of the optical splitter;
the optical emitter generates a plurality of optical outputs from each high reflectivity facet of the plurality of optical gain elements with an optical emission spectrum defined by the wavelength dependent reflective filters of the plurality R wavelength dependent reflective filters coupled to the optical splitter by the optical switch;
R is an integer greater than or equal to 1;
N is an integer greater than or equal to 2;
T is an integer greater than or equal to 1; and
M is an integer greater than or equal to 1.

7. The optical emitter according to claim 1, wherein
the wavelength specific optical portion comprises:
a wavelength dependent reflective filter settable to a predetermined centre wavelength within a defined wavelength range and a predetermined passband; and
the optical gain portion comprises:
a first optical gain element forming part of an external cavity laser in conjunction with the wavelength dependent reflective filter; and
a plurality N second optical gain elements; wherein
an output port of the external cavity laser is coupled to an input port of an isolator;
an output port of the isolator is coupled to an input port of a 1×N optical splitter;
an end of optical gain element of the plurality N second optical gain elements is coupled to a defined output port of the optical splitter;
the optical emitter generates a plurality of optical outputs from a distal end of each of the plurality N second optical gain elements with an optical emission spectrum defined by the wavelength dependent reflective filter; and
N is an integer greater than or equal to 2.

8. The optical emitter according to claim 1, wherein
the wavelength specific optical portion comprises:
a first wavelength dependent reflective filter having a predetermined passband and a first free spectral range settable to a predetermined centre wavelength within a defined wavelength range; and
a second wavelength dependent reflective filter having a predetermined passband and a second free spectral range settable to another predetermined centre wavelength within the defined wavelength range; and
an N×2 optical splitter having N input ports, a first output port coupled to the first wavelength dependent reflective filter and a second output port coupled to the second wavelength dependent reflective filter; and
the optical gain portion comprises:
a plurality of N optical gain elements each having an input port and an output port; wherein
the input port of each optical gain element of the plurality N optical gain elements is coupled to a predetermined input port of the N×2 optical splitter;
each output port of each optical gain element of the plurality of optical gain elements is optically coupled to a high reflectivity facet;
the optical emitter generates one or more outputs at a wavelength where the reflectivity of the first wavelength dependent reflective filter and the second wavelength dependent reflective filter align; and
N is an integer greater than or equal to 2.

9. The optical emitter according to claim 1, wherein
the wavelength specific optical portion comprises:
a first wavelength dependent reflective filter having a predetermined passband and a first free spectral range settable to a predetermined centre wavelength within a defined wavelength range; and
a second wavelength dependent reflective filter having a predetermined passband and a second free spectral range settable to another predetermined centre wavelength within the defined wavelength range; and
an N×2 optical splitter having N input ports, a first output port coupled to the first wavelength dependent reflective filter and a second output port coupled to the second wavelength dependent reflective filter; and
the optical gain portion comprises:
a plurality of N optical gain elements each having an input port and an output port; wherein
the input port of each optical gain element of the plurality N optical gain elements is coupled to a predetermined input port of the N×2 optical splitter;
each output port of each optical gain element of the plurality of optical gain elements is optically coupled to a high reflectivity facet;
the optical emitter generates one or more outputs at a wavelength defined by a vernier overlay of the periodic wavelength response defined by the first free spectral range of the first wavelength dependent reflective filter and the other periodic wavelength response defined by the second free spectral range of the second wavelength dependent reflective filter; and
N is an integer greater than or equal to 2.

10. The optical emitter according to claim 1, wherein
the optical gain portion comprises an optical splitter coupled to the wavelength specific optical portion having a plurality N outputs;
an output of the N outputs of the optical splitter is coupled to a wavelength locker;
the other N−1 outputs of the optical splitter each comprise an optical gain element and a high reflectivity reflector; and
N is an integer greater than or equal to 2.

11. The optical emitter according to claim 1, wherein
the wavelength specific optical portion comprises:
a plurality of wavelength selective optical switch (WSOS) elements coupled in series wherein the first WSOS element of the plurality of WSOS elements is coupled to a first input port of the wavelength specific optical portion and each sequential WSOS element of the plurality of WSOS elements has a free spectral range (FSR) equal to the FSR of the preceding WSOS of the plurality of WSOS elements multiplied by a first constant;
a plurality of gates where each gate is disposed between an output port of the wavelength specific optical portion and a high reflectivity reflector and is configurable to either pass optical signals from the output port of the wavelength specific optical portion to the high reflectivity reflector or block the optical signals; and
the optical emitter generates one or more outputs at a wavelength defined by which gate or gates pass optical signals from their output port of the wavelength specific optical portion to the associated high reflectivity reflector.

12. The optical emitter according to claim 1, wherein
the wavelength specific optical portion comprises:
a plurality of wavelength selective optical switch (WSOS) elements coupled in series wherein the first WSOS element of the plurality of WSOS elements is coupled to a first output of an input port of the wavelength specific optical portion and each sequential WSOS element of the plurality of WSOS elements has a free spectral range (FSR) equal to the FSR of the preceding WSOS of the plurality of WSOS elements multiplied by a first constant;
a plurality of gates where each gate is disposed between an output port of the wavelength specific optical portion and a high reflectivity reflector and is configurable to either pass optical signals from the output port of the wavelength specific optical portion to the high reflectivity reflector or block the optical signals;
the optical emitter generates one or more outputs at a wavelength defined by which gate or gates pass optical signals from their output port of the wavelength specific optical portion to the associated high reflectivity reflector; and
each WSOS element of the plurality of WSOS elements comprises an optical de-interleaver (D-INT) having a pair of outputs and an optical switch (OS) coupled to the pair of outputs of the D-INT;
in the first state the OS selects an output of the pair of outputs of the D-INT; and
in the second state the OS selects the other output of the pair of outputs of the D-INT.

13. The optical emitter according to claim 1, wherein
the wavelength specific optical portion comprises:
a plurality of wavelength selective optical switch (WSOS) elements coupled in series wherein the first WSOS element of the plurality of WSOS elements is coupled to a first output of an input port of the wavelength specific optical portion and each sequential WSOS element of the plurality of WSOS elements has a free spectral range (FSR) equal to the FSR of the preceding WSOS of the plurality of WSOS elements multiplied by a first constant;
each WSOS element of the plurality of WSOS elements is dynamically configurable between a first state and a second state such that the plurality of WSOS elements filter an incoming optical stream of a plurality optical signals having a predetermined channel spacing;
in the first state each WSOS element of the plurality of WSOS elements passes a first subset of those wavelengths coupled to it; and
in the second state each WSOS element of the plurality of WSOS elements passes a second subset of those wavelengths coupled to it.

14. The optical emitter according to claim 1, wherein
the wavelength specific optical portion comprises:
a plurality of wavelength selective optical switch (WSOS) elements coupled in series wherein the first WSOS element of the plurality of WSOS elements is coupled to a first output of an input port of the wavelength specific optical portion and each sequential WSOS element of the plurality of WSOS elements has a free spectral range (FSR) equal to the FSR of the preceding WSOS of the plurality of WSOS elements multiplied by a first constant;
each WSOS element of the plurality of WSOS elements is dynamically configurable between a first state and a second state such that the plurality of WSOS elements filter an incoming optical stream of a plurality optical signals having a predetermined channel spacing;
in the first state each WSOS element of the plurality of WSOS elements passes a first subset of those wavelengths coupled to it;
in the second state each WSOS element of the plurality of WSOS elements passes a second subset of those wavelengths coupled to it;
each WSOS element of the plurality of WSOS elements comprises an optical de-interleaver (D-INT) having a pair of outputs and an optical switch (OS) coupled to the pair of outputs of the D-INT where in the first state the OS selects an output of the pair of outputs of the D-INT and in the second state the OS selects the other output of the pair of outputs of the D-INT.
